(19) United States
(12) Patent Application Publication
(10) Pub. No.: US 2026/0215044 A1
(43) Pub. Date: Jul. 23, 2026

(54) LIGHT-EMITTING DEVICE

(71) Applicant: Stanley Electric Co., Ltd., Tokyo (JP)

(72) Inventors: Shun IWAMOTO, Tokyo (JP); Kaori TACHIBANA, Tokyo (JP)

(73) Assignee: Stanley Electric Co., Ltd., Tokyo (JP)

(21) Appl. No.: 19/138,703

(22) PCT Filed: Dec. 18, 2023
(86) PCT No.: PCT/JP2023/045301

§ 371 Date: Jun. 13, 2025

(30) Foreign Application Priority Data
Dec. 16, 2022 (JP) 2022-201201

(51) Int. Cl. H10H 20/856; H10H 20/851; H10H 20/855

(52) U.S. Cl. CPC H10H 20/856; H10H 20/8514; H10H 20/855

(57) ABSTRACT

A light-emitting device includes a substrate, a light-emitting portion, an optical functional unit, a spacer portion, a light reflecting portion, and a low refractive-index portion. The light-emitting portion is disposed on the substrate, includes a semiconductor light-emitting element with a light-emitting layer, and has a top surface from which an emitted light from the light-emitting layer is emitted. The optical functional unit is made of a transparent material and includes a base portion and a plurality of projections formed on the base portion. The base portion continuously extend to cover the top surface of the light-emitting portion. The spacer portion separates the top surface of the light-emitting portion and a lower surface of the base portion opposed to each other by a predetermined distance to form a gap between the top surface of the light-emitting portion and the lower surface of the base portion.

### TECHNICAL FIELD

The present invention relates to a light-emitting device including a light-emitting element and a method for manufacturing the same.

### BACKGROUND ART

Conventionally, there has been known a light-emitting device using a light-emitting element, such as a Light Emitting Diode (LED), as a light source.

For example, Patent Document 1 discloses a light-emitting module that includes a semiconductor light-emitting element, and a light wavelength conversion member and a transparent member stacked on the semiconductor light-emitting element, in which a plurality of protrusions are provided on the transparent member.

Patent Document 1: JP-A-2010-219163

### DISCLOSURE OF THE INVENTION

### Problems to be Solved by the Invention

For example, in the light-emitting module as disclosed in Patent Document 1, when a light incident from a lower surface of the transparent member is emitted upward, the light spreads in a direction perpendicular to the light-emitting module, that is, a lateral direction with respect to the optical axis, and the light is emitted in a wide angle based on the optical axis. Therefore, it is difficult to apply the light-emitting module that emits a light in a wide angle to a device that requires a narrow-angle component.

The present invention is made in consideration of the above-described point, and it is an object of the present invention to provide a light-emitting device capable of narrowing an angle of an emitted light from the light-emitting device.

### Solutions to the Problems

A light-emitting device according to the present invention includes a substrate, a light-emitting portion, an optical functional unit, a spacer portion, a light reflecting portion, and a low refractive-index portion. The light-emitting portion is disposed on the substrate, includes a semiconductor light-emitting element with a light-emitting layer, and has a top surface from which an emitted light from the light-emitting layer is emitted. The optical functional unit is made of a transparent material and includes a base portion and a plurality of projections formed on the base portion. The base portion continuously extend to cover the top surface of the light-emitting portion. The spacer portion separates the top surface of the light-emitting portion and a lower surface of the base portion opposed to each other by a predetermined distance to form a gap between the top surface of the light-emitting portion and the lower surface of the base portion. The light reflecting portion is made of a material with a light reflectivity and covers a side surface of the light-emitting portion, a side surface of the spacer portion, or at least a part of a side surface of the base portion. The low refractive-index portion is provided inside the gap and made of a low refractive-index material having a small refractive index compared with the optical functional unit.

### BRIEF DESCRIPTION OF THE DRAWINGS

FIG. 1 is a top view of a light-emitting device according to Embodiment 1 of the present invention.

FIG. 2 is a cross-sectional view of the light-emitting device according to Embodiment 1 of the present invention.

FIG. 3 is a drawing illustrating optical paths of a light-emitting device according to a comparative example.

FIG. 4 is a drawing illustrating optical paths of the light-emitting device according to Embodiment 1 of the present invention.

FIG. 5 is a drawing illustrating a directivity of an emitted light from the light-emitting device according to Embodiment 1 of the present invention.

FIG. 6 is a drawing illustrating a narrow-angle luminous flux amount ratio based on a thickness of a low refractive-index portion of the light-emitting device according to Embodiment 1 of the present invention.

FIG. 7 is a drawing illustrating the narrow-angle luminous flux amount ratio based on a thickness of a base portion of an optical functional unit of the light-emitting device according to Embodiment 1 of the present invention.

FIG. 8 is a drawing illustrating the narrow-angle luminous flux amount ratio based on a radius of a projection of the light-emitting device according to Embodiment 1 of the present invention.

FIG. 9 is a drawing illustrating an example of the number of the projections to be arranged in the light-emitting device according to Embodiment 1 of the present invention.

FIG. 10 is a drawing illustrating the narrow-angle luminous flux amount ratio based on the number of the projections to be arranged in the light-emitting device according to Embodiment 1 of the present invention.

FIG. 11 is a drawing illustrating an example of an arrangement of first projections and second projections in the light-emitting device according to Embodiment 1 of the present invention.

FIG. 12 is a drawing illustrating the narrow-angle luminous flux amount ratio based on a radius of the second projection of the light-emitting device according to Embodiment 1 of the present invention.

FIG. 13 is a top view of a light-emitting device according to Modification 1 of the present invention.

FIG. 14 is a cross-sectional view of the light-emitting device according to Modification 1 of the present invention.

FIG. 15 is a cross-sectional view of the light-emitting device according to Modification 1 of the present invention.

FIG. 16 is a cross-sectional view of a light-emitting device according to Modification 2 of the present invention.

FIG. 17 is a cross-sectional view of a light-emitting device according to Modification 3 of the present invention.

FIG. 18 is a cross-sectional view of a light-emitting device according to Modification 4 of the present invention.

FIG. 19 is a cross-sectional view of a light-emitting device according to Modification 5 of the present invention.

FIG. 20 is a cross-sectional view of a light-emitting device according to Modification 6 of the present invention.

FIG. 21 is a cross-sectional view of a light-emitting device according to Modification 7 of the present invention.

FIG. 22 is a cross-sectional view of a light-emitting device according to Modification 8 of the present invention.

FIG. 23 is a cross-sectional view of a light-emitting device according to Modification 9 of the present invention.

FIG. 24 is a cross-sectional view of a light-emitting device according to Modification 10 of the present invention.

FIG. 25 is a top view of a light-emitting device according to Modification 11 of the present invention.

FIG. 26 is a cross-sectional view of the light-emitting device according to Modification 11 of the present invention.

FIG. 27 is a cross-sectional view of a light-emitting device according to Modification 12 of the present invention.

FIG. 28 is a cross-sectional view of a light-emitting device according to Modification 13 of the present invention.

FIG. 29 is a top view of a light-emitting device according to Modification 14 of the present invention.

FIG. 30 is a cross-sectional view of the light-emitting device according to Modification 14 of the present invention.

FIG. 31 is a cross-sectional view of a light-emitting device according to Modification 15 of the present invention.

FIG. 32 is a cross-sectional view of a light-emitting device according to Modification 16 of the present invention.

FIG. 33 is a cross-sectional view of a light-emitting device according to Modification 17 of the present invention.

FIG. 34 is a top view of a light-emitting device according to Modification 18 of the present invention.

FIG. 35 is a cross-sectional view of the light-emitting device according to Modification 18 of the present invention.

FIG. 36 is a cross-sectional view of a light-emitting device according to Modification 19 of the present invention.

FIG. 37 is a cross-sectional view of a light-emitting device according to Modification 20 of the present invention.

FIG. 38 is a cross-sectional view of a light-emitting device according to Modification 21 of the present invention.

FIG. 39 is a cross-sectional view of a light-emitting device according to Modification 22 of the present invention.

FIG. 40 is cross-sectional views of the light-emitting device according to Modification 22 of the present invention.

FIG. 41 is a drawing illustrating the narrow-angle luminous flux amount ratio based on the number of the projections to be arranged and the thickness of the low refractive-index portion of the light-emitting device according to Embodiment 1 of the present invention.

FIG. 42 is a top view of a light-emitting device according to Embodiment 2 of the present invention.

FIG. 43 is a cross-sectional view of the light-emitting device according to Embodiment 2 of the present invention.

FIG. 44 is a drawing schematically illustrating an opening angle of a second part of a projection of the light-emitting device according to Embodiment 2 of the present invention.

FIG. 45 is a drawing illustrating a narrow-angle luminous flux amount ratio based on the opening angle of the second part of the projection of the light-emitting device according to Embodiment 2 of the present invention.

FIG. 46 is a drawing illustrating the narrow-angle luminous flux amount ratio based on a thickness of a base portion of an optical functional unit of the light-emitting device according to Embodiment 2 of the present invention.

FIG. 47 is a drawing illustrating the optical paths of the light-emitting device according to Embodiment 1 of the present invention.

FIG. 48 is a drawing illustrating optical paths of the light-emitting device according to Embodiment 2 of the present invention.

### DESCRIPTION OF PREFERRED EMBODIMENTS

Embodiment 1 of the present invention is described in detail below. In the following description and the attached drawings, the same reference numerals are attached to substantially same or equivalent parts.

### Embodiment 1

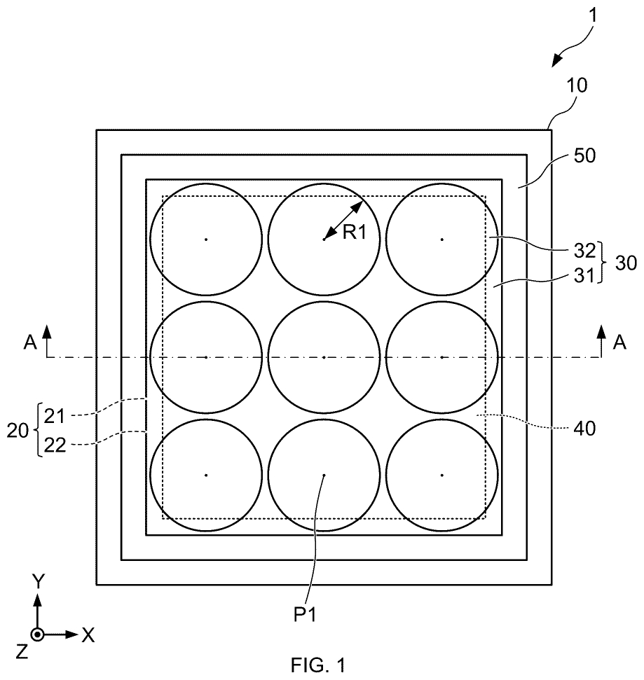

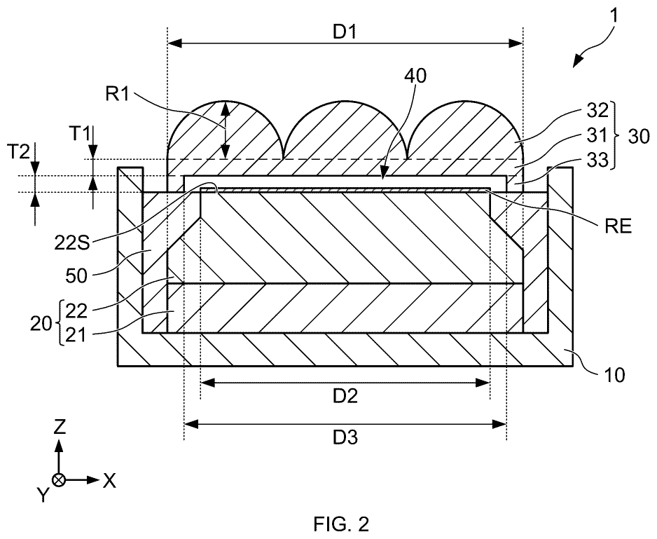

With reference to FIG. 1 and FIG. 2, a configuration of a light-emitting device 1 according to Embodiment 1 is described. FIG. 1 is a top view of the light-emitting device 1 according to Embodiment 1. FIG. 2 is a cross-sectional view of the light-emitting device 1 taken along a line A-A illustrated in FIG. 1.

### (Light-Emitting Device)

The light-emitting device 1 includes a substrate 10, a light-emitting portion 20 including a semiconductor light-emitting element 21 disposed on the substrate 10 and a wavelength conversion member 22 disposed on a top surface of the semiconductor light-emitting element 21, an optical functional unit 30 disposed above the light-emitting portion 20, a low refractive-index portion 40 disposed between a top surface of the light-emitting portion 20 and a lower surface of the optical functional unit 30, and a light reflecting member 50 that covers a side surface of the light-emitting portion 20.

### (Substrate)

The substrate 10 is an insulating substrate that has a rectangular top surface shape and is made of ceramic, such as aluminum nitride (AlN). The substrate 10 has a top surface provided with a recess that has a rectangular bottom surface in one region at the center of the top surface and is open upward.

The substrate 10 may be integrally formed so as to be provided with the recess opening upward, and may be formed in a manner in which a flat plate is joined with a frame body having a frame shape along an outer edge of the flat plate. For the substrate 10, an insulating material, such as a resin material other than ceramic, may be used.

The substrate 10 includes a pair of wiring electrodes (not illustrated) that are made of metal and configured to feed a power to the semiconductor light-emitting element 21 from outside the substrate 10 at the bottom surface of the recess. For example, the wiring electrodes are formed to be electrically conductive to the outside of the substrate 10 via through electrodes and the like (not illustrated).

### (Light-Emitting Element)

The semiconductor light-emitting element 21 is a light emitting diode (LED) that has a rectangular top surface shape and includes a gallium nitride (GaN) based semiconductor structure layer with a light-emitting layer emitting a blue light. As illustrated in FIG. 2, the semiconductor light-emitting element 21 is disposed on the bottom surface of the recess of the substrate 10 such that a side surface of the semiconductor light-emitting element 21 is spaced from an internal surface of the recess of the substrate 10.

The semiconductor light-emitting element 21 is a flip-chip type LED element in which a semiconductor structure layer (not illustrated) and a pair of element electrodes (not illustrated) are provided on a lower surface of a transparent growth substrate (not illustrated) and a light is emitted from a top surface of the growth substrate. That is, the top surface of the semiconductor light-emitting element 21 is a light-emitting surface that emits a light.

The pair of element electrodes of the semiconductor light-emitting element 21 are electrically connected to the pair of respective wiring electrodes formed on the bottom surface of the recess of the substrate 10. That is, the semiconductor light-emitting element 21 is mounted on the substrate 10 in the flip-chip manner, and configured to be able to receive electric power supply from outside via the wiring electrodes formed on the substrate 10, thus being able to be energized.

A light reflection layer may be formed on a lower surface of the semiconductor structure layer of the semiconductor light-emitting element 21, especially between the semiconductor structure layer and the pair of element electrodes. A light emitted downward in an opposite side of the growth substrate may be reflected by the light reflection layer to be traveled toward the top surface as the light-emitting surface of the semiconductor light-emitting element 21, thereby improving a light extraction efficiency from the top surface of the growth substrate as a light-emitting surface.

In Embodiment 1, the semiconductor light-emitting element 21 is, for example, a light-emitting element having a chip size of a square in which a length D1 of one side of a top surface shape is about 1.0 mm. In this case, the light-emitting surface of the semiconductor light-emitting element 21 is a square with one side of about 1.0 mm.

The semiconductor light-emitting element 21 is not limited to the above-described structure, and may be a flip-chip type semiconductor light-emitting element having another chip size. The semiconductor light-emitting element may have a top surface shape in a rectangular shape, such as a rectangle.

For the semiconductor light-emitting element 21, an LED element of another connection configuration can be used. For example, the semiconductor light-emitting element 21 may be a wire bonding type light-emitting element that includes a support substrate, a semiconductor structure layer disposed on a top surface of the support substrate, and an electrode pad disposed on the semiconductor structure layer so as to be able to be wire-bonded, in which a pair of wirings are electrically connected to the electrode pad with an electrically conductive metal wire of aurum (Au) or the like.

The semiconductor light-emitting element 21 may be a light-emitting element in which a semiconductor structure layer provided on a top surface of a support substrate and a pair of electrode pads formed on the top surface of the support substrate are electrically connected by a metal wiring formed to be extended on the semiconductor structure layer and the support substrate, or may be a light-emitting element in which a semiconductor structure layer can be energized between an electrode formed on a lower surface of a conductive support substrate and an electrode formed on the support substrate. In this case, it is only necessary to make a design with a length of one side of the top surface of the semiconductor structure layer formed on the top surface of the support substrate defined as D1.

In Embodiment 1, the semiconductor light-emitting element 21 only needs to be an element that emits a light from an opposite surface of a surface opposed to the bottom surface of the recess of the substrate 10, that is, the top surface.

As described above, while the case of the semiconductor light-emitting element 21 having the square top surface (light-emitting surface) shape is described in Embodiment 1, the shape of the light-emitting surface of the semiconductor light-emitting element 21 only needs to be a rectangular shape. For example, in a case of a rectangle, the shape of the light-emitting surface of the semiconductor light-emitting element 21 can be 0.1% or more and 20% or less of a long side thereof and 0.1% or more and 20% or less of a short side thereof.

### (Wavelength Conversion Member)

The wavelength conversion member 22 is disposed on the top surface of the semiconductor light-emitting element 21 via a transparent adhesive (not illustrated).

As illustrated in FIG. 2, the wavelength conversion member 22 is formed to have a bottom surface that covers the light-emitting surface of the semiconductor light-emitting element 21, that is, the top surface of the semiconductor light-emitting element 21. Therefore, the bottom surface of the wavelength conversion member 22 is a light incident surface on which the light emitted from the semiconductor light-emitting element 21 is incident in the wavelength conversion member 22.

The light incident from the light incident surface as the bottom surface of the wavelength conversion member 22 is guided to a top surface 22S from the bottom surface, and is emitted from the top surface. Here, the light traveling toward a side surface of the wavelength conversion member 22 in the light incident from the light incident surface as the bottom surface of the wavelength conversion member 22 is reflected to the wavelength conversion member 22 side by the light reflecting member 50 described later, and emitted from the top surface 22S of the wavelength conversion member 22. That is, the top surface 22S of the wavelength conversion member 22 is a light-emitting surface of the wavelength conversion member 22, that is, a light-emitting surface of the light-emitting portion 20.

The wavelength conversion member 22 can be configured to be slightly larger than the top surface of the semiconductor light-emitting element 21. The transparent adhesive between the semiconductor light-emitting element 21 and the wavelength conversion member 22 is preferably formed to reach the side surface of the semiconductor light-emitting element 21 and cover the side surface of the semiconductor light-emitting element 21 in a fillet shape. In this case, with the light reflecting member 50 that covers the fillet-shaped adhesive side surface, the light emitted from the side surface of the semiconductor light-emitting element 21 can be efficiently guided to and incident on the wavelength conversion member 22. That is, the light reflecting member 50 is configured to cover the semiconductor light-emitting element side surface via the fillet-shaped adhesive side surface.

The wavelength conversion member 22 is, for example, a ceramic material made of alumina (Al₂O₃) containing yttrium aluminum garnet phosphor particles with cerium (Ce) as an activator agent (YAG:Ce). The wavelength conversion member 22 converts a part of blue light that is incident from the bottom surface as the light incident surface and emitted from the semiconductor light-emitting element 21 into a yellow light, and emits a white light from the top surface 22S as the light-emitting surface.

In Embodiment 1, the bottom surface of the wavelength conversion member 22 is formed to have a shape approximately matched with the top surface of the semiconductor light-emitting element 21. That is, when the semiconductor light-emitting element 21 is a chip having the square top surface shape in which the length D1 of one side is approximately 1.0 mm exemplified as described above, the bottom surface of the wavelength conversion member 22 is also a square having a length of one side of the bottom surface equal to the length D1 of one side of the semiconductor light-emitting element 21 exemplified as described above.

As the approximately matched shape, for the size, about 0.1 mm for each side is acceptable as an error, the range for each side only needs to be 0.9 mm or more and 1.1 mm or less, and the range for each side may be 0.8 mm or more and 1.2 mm or less depending on the element form and the like.

Furthermore, the bottom surface shape of the wavelength conversion member 22 is formed corresponding to a light-emitting region in the top surface of the semiconductor light-emitting element 21 depending on the aspect of the semiconductor light-emitting element 21. While the top surface of the semiconductor light-emitting element 21 constitutes the light-emitting surface of the semiconductor light-emitting element 21 and the top surface of the semiconductor light-emitting element 21 is the light-emitting region in Embodiment 1, the entire top surface of the semiconductor light-emitting element 21 might not be entirely the light-emitting region depending on the configuration of the semiconductor light-emitting element 21.

For example, when the light-emitting region and a wire bonding electrode pad are separately formed with respect to the semiconductor light-emitting element 21 including an electrode power-fed by the wire the bonding, the wavelength conversion member 22 is formed in a shape covering only the light-emitting region without covering the wire bonding electrode pad part. That is, the bottom surface shape of the wavelength conversion member 22 is a shape approximately matched with the shape of the light-emitting region in the top surface of the semiconductor light-emitting element 21.

As illustrated in FIG. 2, the wavelength conversion member 22 has an inclined surface inclined inward at the side surface, and is formed to narrow upward from the bottom surface. That is, the wavelength conversion member 22 has a quadrangular prism-shaped lower part extending in a perpendicular direction from the bottom surface, a truncated square pyramid-shaped middle part that is formed on the lower part and has the inclined side surface, and a quadrangular prism-shaped upper part formed on the middle part. In other words, the wavelength conversion member 22 has a shape in which the quadrangular prism shape, the truncated square pyramid shape, and the quadrangular prism shape are integrally formed upward from the bottom surface. The lower part side surface and the middle part side surface, and the middle part side surface and the upper part side surface are continuously formed.

With the wavelength conversion member 22 having the truncated square pyramid-shaped middle part, the light incident from the light incident surface of the wavelength conversion member 22 is reflected on the inclined surface of the middle part, thereby allowing collecting the light to the top surface 22S as the light-emitting surface of the wavelength conversion member 22. Accordingly, a luminance of the light emitted from the top surface 22S of the wavelength conversion member 22 can be increased.

In Embodiment 1, the shape of the top surface 22S of the wavelength conversion member 22 is the square in a similarity shape to the bottom surface. In Embodiment 1, a length D2 of one side of the top surface 22S of the wavelength conversion member 22 is set to about 0.85 mm.

Dimensions of the top surface 22S of the wavelength conversion member 22 are not limited to those described above, and may be other dimensions. The top surface 22S of the wavelength conversion member 22 may have a rectangular shape, such as a rectangle.

In Embodiment 1, for example, a transparent coating layer RE having a low affinity to a resin material having translucency and constituting the light reflecting member 50 described below is formed on a surface of the top surface 22S of the wavelength conversion member 22. The coating layer RE can be configured of, for example, a fluororesin having a property of repelling an uncured resin. This makes it possible to keep the resin material, such as an adhesive, for joining the light reflecting member 50 or the optical functional unit 30 described below, from creeping up onto the top surface 22S of the wavelength conversion member 22. The coating layer RE can be, for example, formed to have a thickness of 1 nm or more and 1 μm or less, and configured so as to leave unevenness formed on the top surface 22S of the wavelength conversion member 22 on a surface thereof, therefore, a luminous efficiency can be maintained even when the coating layer RE is provided.

### (Optical Functional Unit)

The optical functional unit 30 is a member that is disposed on the top surface 22S of the wavelength conversion member 22 and includes a flat plate-shaped base portion 31, a plurality of projections 32 formed on a top surface of the base portion 31, and a spacer portion 33 formed on a lower surface of the base portion 31, which are integrally formed. The optical functional unit 30 is, for example, a lens array body made of a silicone resin with a refractive index n=1.41.

The light emitted from the top surface 22S of the wavelength conversion member 22 is incident on the lower surface of the base portion 31 via the low refractive-index portion 40 described below, propagates inside the optical functional unit 30, and is emitted to the outside of the light-emitting device 1 from the surfaces of the projections 32. That is, the lower surface of the base portion 31 of the optical functional unit 30 functions as the light incident surface of the optical functional unit 30, and the respective surfaces of the projections 32 function as the light-emitting surface of the optical functional unit 30.

The base portion 31 is a flat plate-shaped part that covers the top surface 22S of the wavelength conversion member 22. In Embodiment 1, a shape of the top surface of the base portion 31 is a shape approximately matched with the top surface of the semiconductor light-emitting element 21 and the bottom surface of the wavelength conversion member 22. In other words, in Embodiment 1, the top surface of the semiconductor light-emitting element 21, the bottom surface of the wavelength conversion member 22, and the outer shape of the base portion 31 are each approximately equal to the length D1 of one side of the top surface of the semiconductor light-emitting element 21. As the shape of the base portion 31 approximately matched with the top surface of the semiconductor light-emitting element 21 and the bottom surface of the wavelength conversion member 22, the size of respective sides of about 0.1 mm is acceptable as an error, the range for each side only needs to be 0.9 mm or more and 1.1 mm or less, and the range for each side may be 0.8 mm or more and 1.2 mm or less depending on the element form and the like.

In Embodiment 1, a thickness T1 of the base portion 31 is set to about 50 μm.

The projection 32 is a hemispherical lens formed to project upward on the top surface of the base portion 31. As illustrated in FIG. 1, the projections 32 are arranged in a symmetry with respect to a center point of the top surface of the base portion 31 on the top surface of the base portion 31.

In Embodiment 1, the nine projections 32 in total are arranged in a matrix of three rows and three columns on the top surface of the base portion 31 of the optical functional unit 30. The nine projections 32 are arranged in a manner in which the respective projections 32 have center points at center points P1 of respective compartments when the top surface of the base portion 31 of the optical functional unit 30 is equally divided into nine compartments in X and Y directions. Each of the projections 32 is formed in the hemispherical shape having a radius of a radius R1 with the center at the center point P1 in each compartment. Each of the radii R1 of the projections 32 is formed to be 16.5% of the length of one side of the top surface of the base portion 31 (corresponding to the length D1 of one side of the top surface of the semiconductor light-emitting element 21 in Embodiment 1).

In Embodiment 1, the light-emitting surface as the top surface of the light-emitting portion 20 is positioned immediately below each of the projections 32. That is, the top surface of the wavelength conversion member 22 and the top surface of the coating layer RE are positioned immediately below each of the projections 32. Especially, the top surface of the light-emitting portion 20 (in other words, the top surface of the wavelength conversion member 22 or the top surface of the coating layer RE) is positioned immediately below all the projections disposed at an outermost periphery among the projections 32. Accordingly, compared with a case where the light-emitting portion 20 is not provided immediately below the projections at the outermost periphery, a shape of a light source image projected from the light-emitting device 1 can be made similar to the top surface shape of the light-emitting portion 20, therefore, ease of design in a usage for designing a shape of a light source image can be improved. For example, the light source image can be formed in an approximately square shape with respect to the square top surface shape of the light-emitting portion 20 in Embodiment 1.

In Embodiment 1, in top view, an outer edge of the top surface of the light-emitting portion 20 (that is, an outer edge of the top surface of the wavelength conversion member 22) is positioned immediately below the projections 32 disposed at the outermost periphery. That is, in Embodiment 1, in top view, an outer edge end portion of the optical functional unit 30 is positioned outside with respect to the outer edge of the top surface of the light-emitting portion 20 (that is, the outer edge of the top surface of the wavelength conversion member 22) in top view. In this case, the outer edge of the top surface of the light-emitting portion 20 (that is, the outer edge of the top surface of the wavelength conversion member 22) is preferably positioned outside with respect to top portions of the projections 32 disposed at the outermost periphery.

The spacer portion 33 is a spacer that separates the top surface 22S of the wavelength conversion member 22 and the bottom surface of the base portion 31 by a predetermined distance.

In Embodiment 1, the spacer portion 33 is a protruding portion that protrudes downward along an outer edge of the lower surface of the base portion 31. In Embodiment 1, the spacer portion 33 is formed to have a height enough to form a gap or a space with a thickness T2 of 50 μm between the top surface 22S of the wavelength conversion member 22 and the lower surface of the base portion 31.

In Embodiment 1, the spacer portion 33 is formed with a width of 50 μm. That is, in the cross-sectional surface of FIG. 2, a length between inner walls of the spacer portions 33 at mutually opposed sides of the base portion 31 is set to about 0.9 mm.

In the optical functional unit 30, a lower surface of the spacer portion 33 is bonded to the top surface of the light reflecting member 50 via a transparent adhesive (not illustrated) in a region of the top surface of the light reflecting member 50 described below. The lower surface of the spacer portion 33 and the top surface of the light reflecting member 50 may be bonded with a resin component of the light reflecting member 50 without the adhesive.

### (Low Refractive-Index Portion)

The low refractive-index portion 40 is a low refractive-index portion in which a low refractive-index material having a refractive index smaller than that of a material constituting the optical functional unit 30 is present in the space formed by the spacer portion 33 of the optical functional unit 30.

In Embodiment 1, in the low refractive-index portion 40, air (refractive index n=1.0) is filled in the space formed by the spacer portion 33 of the optical functional unit 30.

The light emitted from the top surface 22S of the wavelength conversion member 22 is incident on the optical functional unit 30 having the higher refractive index than the low refractive-index portion 40 via the low refractive-index portion 40. Here, the light emitted from the top surface 22S of the wavelength conversion member 22 is incident on the optical functional unit 30 (base portion 31) with an angle narrowed at an interface between the low refractive-index portion 40 and the optical functional unit 30 in an optical axis direction that is a perpendicular direction to the top surface 22S of the wavelength conversion member 22. Therefore, with the low refractive-index portion 40 disposed between the top surface 22S of the wavelength conversion member 22 and the lower surface of the base portion 31 of the optical functional unit 30, a narrow-angle component of the light emitted from the light-emitting device 1 can be increased.

The narrow-angle component of the light emitted from the light-emitting device 1 in this description means a component of a light emitted in a range of 30° with respect to the optical axis direction that is a perpendicular direction to the top surface 22S of the wavelength conversion member 22.

### (Light Reflecting Member)

The light reflecting member 50 is a light reflecting member having light reflectivity filled between the semiconductor light-emitting element 21 and the wavelength conversion member 22 and the inner wall of the recess of the substrate 10 inside the recess of the substrate 10. The light reflecting member 50 is a light reflecting member that covers the respective side surfaces of the semiconductor light-emitting element 21 and the wavelength conversion member 22 and is filled in a manner of exposing the top surface 22S of the wavelength conversion member 22.

In Embodiment 1, for the light reflecting member 50, a transparent resin material, such as a silicone resin, containing light scattering particles, such as titanium oxide (TiO₂) particles, is used.

The light reflecting member 50 reflects or scatters a light that reached the side surface of the semiconductor light-emitting element 21 and the side surface of the wavelength conversion member 22 from the inside so as to return the light to the respective insides. This allows the light reflecting member 50 to avoid leakage of the light that reached the respective side surfaces of the semiconductor light-emitting element 21 and the wavelength conversion member 22 to the outside, and increase an amount of luminous flux emitted from the top surface 22S of the wavelength conversion member 22. That is, by disposing the light reflecting member 50, the light extraction efficiency of the light-emitting device 1 can be improved.

As described above, the optical functional unit 30 is disposed such that the spacer portion 33 is arranged in a region of the top surface of the light reflecting member 50.

For example, when the optical functional unit 30 is joined after curing the silicone resin of the light reflecting member 50, the top surface of the light reflecting member 50 after curing the silicone resin has a recessed surface shape due to resin shrinkage caused by cure shrinkage. At this time, when the lower surface of the spacer portion 33 of the optical functional unit 30 and the top surface of the light reflecting member 50 are joined using an adhesive, the excess of the adhesive in the joining is accumulated in recessed portions of the light reflecting member 50. Therefore, with the resin shrinkage of the light reflecting member 50 and the coating layer RE formed on the top surface 22S of the wavelength conversion member 22, the excess adhesive can avoid climbing onto the top surface 22S of the wavelength conversion member 22.

Also in a case where the optical functional unit 30 is placed on the top surface of the light reflecting member 50 before curing the silicone resin of the light reflecting member 50, and then the silicone resin of the light reflecting member 50 is cured, the coating layer RE on the top surface 22S of the wavelength conversion member 22 makes it possible to keep the silicone resin of the light reflecting member 50 from creeping up onto the top surface 22S of the wavelength conversion member 22.

The light reflecting member 50 may be formed to extend on the inner surface of the recess of the substrate 10, the outer surface of the spacer portion 33 of the optical functional unit 30, and up to a part of a lower end region of the outer surface of the base portion 31 of the optical functional unit 30. In this case, the light reflecting member 50 reflects the light emitted in a lateral direction from the respective outer surfaces of the spacer portion 33 and the base portion 31 of the optical functional unit 30 in the inward direction of the optical functional unit 30, thus allowing suppressing emission of a wide-angle component (light with a directivity of more than ±30° with respect to the optical axis direction) of the emitted light from the light-emitting device 1. In other words, the light reflecting member 50 can suppress the emission of an unintended light, such as a light from the outer surface of the spacer portion 33 and the side surface of the base portion 31 of the optical functional unit 30.

By covering the side surface of the spacer portion 33 of the optical functional unit 30 to support the spacer portion 33, the strength of the spacer portion 33 can be enhanced, thereby suppressing a damage on the spacer portion 33 due to vibration and the like of the spacer portion 33.

### (Action of Low Refractive-Index Portion)

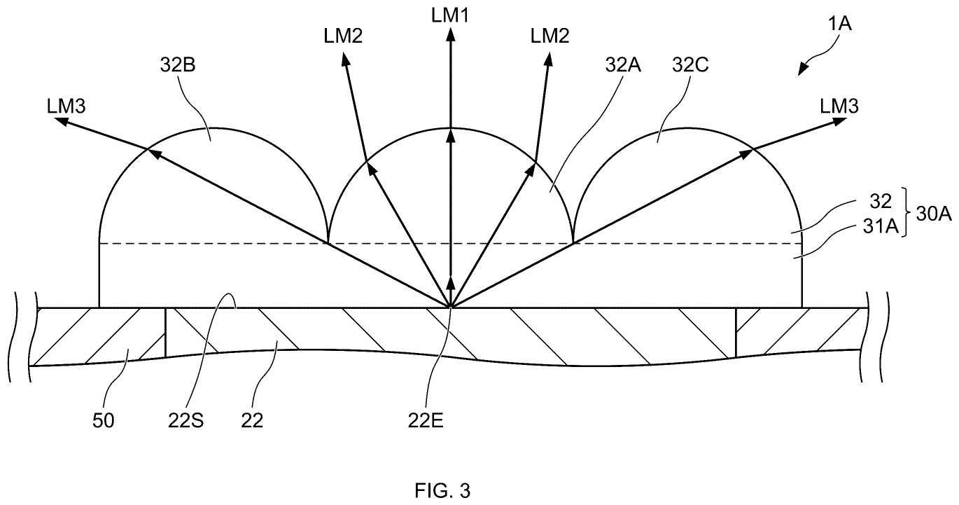

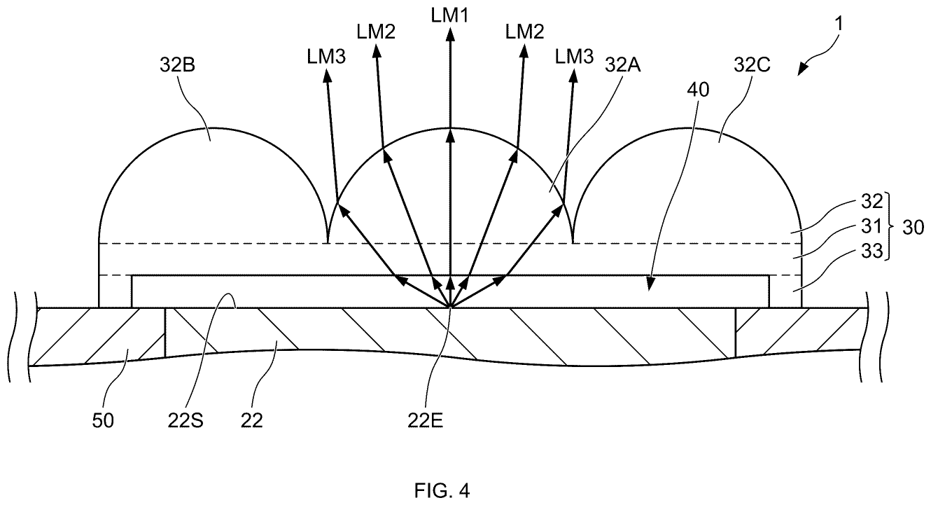

With reference to FIG. 3 and FIG. 4, an action of narrowing the angle of the emitted light from the light-emitting device 1 in Embodiment 1 is described.

FIG. 3 and FIG. 4 are enlarged cross-sectional views of the wavelength conversion member 22 and the optical functional unit 30 in the cross-sectional surface of FIG. 2. To clearly indicate optical paths of emitted lights LM1, LM2, LM3 from the light-emitting device 1, the coating layer RE is not illustrated, and hatching of the optical functional unit 30 is omitted.

FIG. 3 is a drawing illustrating, as a comparative example, optical paths of emitted lights LM1, LM2, LM3 from a light-emitting device 1A that includes an optical functional unit 30A including only a base portion 31A and projections 32 without the low refractive-index portion 40 between the top surface 22S of the wavelength conversion member 22 and the lower surface of the optical functional unit 30.

FIG. 4 is a drawing illustrating the optical paths of the emitted lights LM1, LM2, LM3 from the light-emitting device 1 that includes the low refractive-index portion 40 provided by the spacer portion 33 between the top surface 22S of the wavelength conversion member 22 and the lower surface of the optical functional unit 30 in Embodiment 1.

The base portion 31A of the light-emitting device 1A has a thickness that is a total thickness of the respective thicknesses of the base portion 31 and the spacer portion 33 of the light-emitting device 1.

FIG. 3 and FIG. 4 describe, as a model of the optical paths of the emitted lights LM1 to LM3, a case where a light emitted from a point immediately below the center point of a projection 32A at the center, in other words, a light emission point 22E on the top surface 22S of the wavelength conversion member 22 on a lens axis (optical axis) when the projection 32A is assumed as a lens is diffused and radiated in an ideal Lambertian orientation.

In FIG. 3 and FIG. 4, the emitted light LM1 indicates a light emitted from the top surface 22S of the wavelength conversion member 22 in a direction perpendicular to the top surface 22S. The emitted light LM2 indicates a light emitted from the top surface 22S of the wavelength conversion member 22 to be inclined by 30° with respect to the perpendicular direction. The emitted light LM3 indicates a light emitted from the top surface 22S of the wavelength conversion member 22 to be inclined by 60° with respect to the perpendicular direction.

In FIG. 3, for the emitted lights LM1, LM2, a light emitted from the light emission point 22E of the top surface 22S of the wavelength conversion member 22 is incident in the projection 32A, and emitted from the light-emitting device 1A with an angle narrowed by a lens effect of the surface of the projection 32A.

However, the emitted light LM3 emitted from the light emission point 22E of the wavelength conversion member 22 with a large angle with respect to the axis perpendicular to the top surface 22S, that is, the lens axis (optical axis) of the projection 32A is incident in projections 32B, 32C adjacent to the projection 32A in the base portion 31A. This causes the emitted light LM3 to be refracted in a wide-angle direction (lateral direction of the light-emitting device 1A) by the surface of the projections 32B, 32C and emitted from the light-emitting device 1A with a widened angle.

That is, when a light from the light emission point 22E is incident in the projection 32A and emitted from the surface of the projection 32A, the lens effect of refracting the light in a narrow-angle direction occurs, and the light is refracted in the direction perpendicular to the top surface 22S. However, when the light from the light emission point 22E is incident in the projections 32B and 32C adjacent to the projection 32A, the lens effect of refracting the light in the narrow-angle direction does not occur, and the light is refracted rather in the wide-angle direction.

In contrast, in FIG. 4, the light emitted from the light emission point 22E of the top surface 22S of the wavelength conversion member 22 is incident on the lower surface of the base portion 31 of the optical functional unit 30 via the low refractive-index portion 40.

At this time, the emitted lights LM1, LM2, LM3 are narrowed in angle at the lower surface of the base portion 31 of the optical functional unit 30 in the optical axis direction according to Snell's law, and is easily incident in the projection 32A.

The emitted lights LM1, LM2, LM3 incident in the projection 32A are narrowed in angle by the lens effect of the surface of the projection 32A, and emitted from the light-emitting device 1.

As illustrated in FIG. 3 and FIG. 4, in the light-emitting device 1 of Embodiment 1, the low refractive-index portion 40 is disposed between the top surface 22S of the wavelength conversion member 22 and the lower surface of the base portion 31 of the optical functional unit 30, thereby allowing increase of the narrow-angle component of the emitted light emitted from the light-emitting device 1.

### (Directivity of Emitted Light Form Light-Emitting Device in Embodiment 1)

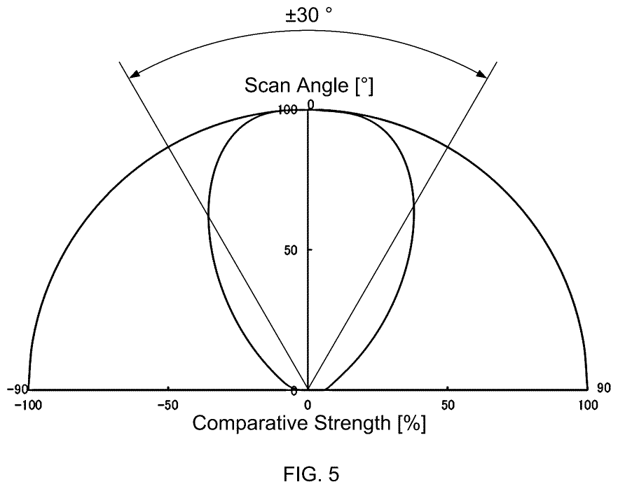

FIG. 5 is a drawing illustrating the directivity of the emitted light form the light-emitting device 1 experimentally produced with the above-described structure.

A perpendicular line 0-0 in FIG. 5 indicates the optical axis direction of the light-emitting device 1. A range of fan shape in FIG. 5 indicates a luminous flux amount ratio in a range of from −90° to +90° with respect to the optical axis direction when the amount of luminous flux in the optical axis direction is assumed to be 100%.

As illustrated in FIG. 5, in the light-emitting device 1 in Embodiment 1, a result that a narrow-angle luminous flux proportion to all the luminous fluxes (a proportion of the luminous flux amount in a range of from −30° to +30° with respect to the optical axis direction to all the luminous fluxes) increases was obtained.

When the narrow-angle luminous flux proportion in a light-emitting device in which an optical output is same as that of the light-emitting device 1 and the emitted light has the directivity of the ideal Lambertian orientation is assumed to be 100%, the narrow-angle luminous flux proportion of the light-emitting device 1 in Embodiment 1 was the narrow-angle luminous flux proportion of 137% to the narrow-angle luminous flux proportion of the light-emitting device having the directivity of the ideal Lambertian orientation.

Accordingly, by disposing the low refractive-index portion 40 between the top surface 22S of the wavelength conversion member 22 and the lower surface of the base portion 31 of the optical functional unit 30, the narrow-angle luminous flux proportion of the emitted light emitted from the light-emitting device 1 can be increased.

### (Verification of Thickness of Low Refractive-Index Portion)

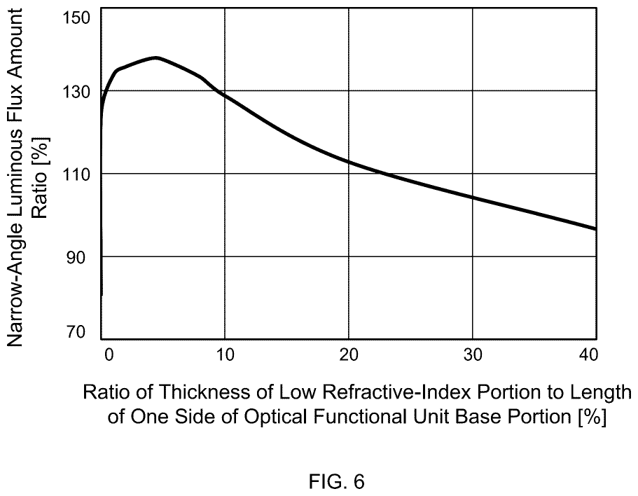

FIG. 6 is a drawing illustrating a simulation result of the luminous flux amount ratio of the narrow-angle component of the light emitted from the light-emitting device 1 when the height of the spacer portion 33 of the optical functional unit 30, that is, the thickness T2 of the low refractive-index portion 40 is changed.

In FIG. 6, the simulation was performed with the light-emitting portion 20 in which, similarly to Embodiment 1, the semiconductor light-emitting element 21 has the square light-emitting surface with the length D1 of one side of 1.0 mm and the top surface 22S of the wavelength conversion member 22 has the square top surface with the length D2 of one side of 0.85 mm.

In FIG. 6, the simulation was performed with the optical functional unit 30 in which the base portion 31 has the square outer shape having one side of 1.0 mm, the radius R1 of the projection 32 is set to 16.5% of the length of one side of the top surface of the base portion 31, and the arrangement is a matrix of three rows and three columns on the base portion 31. The simulation was performed with the optical functional unit 30 in which the thickness T1 of the base portion 31 is set to a thickness of 5% of the length of one side of the top surface of the base portion 31, that is, the thickness T1 of the base portion 31 is set to 50 μm.

In other words, in this simulation, the thickness of the low refractive-index portion 40 was varied with the height of the spacer portion 33 as a parameter in the structure of Embodiment 1.

The horizontal axis of FIG. 6 indicates a ratio of the thickness T2 of the low refractive-index portion 40 to the length of one side of the top surface of the base portion 31 of the optical functional unit 30. A point of 0% of the ratio of the thickness T2 of the low refractive-index portion 40 on the horizontal axis of FIG. 6 indicates a state where the low refractive-index portion 40 is not provided in the light-emitting device 1, that is, a state where the spacer portion 33 is not disposed and the lower surface of the base portion 31 is in contact with the top surface 22S of the wavelength conversion member 22.

In this simulation, as described above, the simulation is performed with the ratio between the thickness T1 of the base portion 31 of the optical functional unit 30 and the thickness T2 of the low refractive-index portion 40 based on the length of one side of the top surface of the base portion 31. For example, when the size of the light-emitting surface of the light-emitting device 1, that is, the length of one side of the outer shape of the base portion 31 is varied, the radius of the projection 32 also varies in accordance with this. Therefore, this is because, since incidence regions in the respective projections 32 of the light emitted from the top surface 22S of the wavelength conversion member 22 also vary, optimal values of the thickness T1 of the base portion 31 of the optical functional unit 30 and the thickness T2 of the low refractive-index portion 40 also vary in accordance with the size of the light-emitting surface of the light-emitting device 1.

The vertical axis of FIG. 6 indicates the luminous flux amount ratio in a narrow angle range (+30°) when the ratio of the thickness T2 of the low refractive-index portion 40 is changed. On the vertical axis of FIG. 6, the amount of luminous flux in a narrow angle of a light-emitting device that is not provided with the optical functional unit 30 and emits a light having a directivity of the ideal Lambertian orientation from the top surface of the wavelength conversion member is assumed to be 100%. In the light-emitting device that emits the light having the directivity of the ideal Lambertian orientation, the top surface shape of the wavelength conversion member is set to a square having one side of 1.0 mm.

As illustrated in FIG. 6, by disposing the low refractive-index portion 40 between the top surface 22S of the wavelength conversion member 22 and the lower surface of the base portion 31, the narrow-angle luminous flux amount ratio increases.

Specifically, in a range in which the ratio of the thickness T2 of the low refractive-index portion 40 to the length of one side of the top surface of the base portion 31 of the optical functional unit 30 is 0.01% or more and 22.8% or less, the narrow-angle luminous flux amount ratio became 110% or more. Furthermore, in a range in which the ratio of the thickness T2 of the low refractive-index portion 40 to the length of one side of the top surface of the base portion 31 of the optical functional unit 30 is 0.6% or more and 9.4% or less, the narrow-angle luminous flux amount ratio became 130% or more.

At a position at which the ratio of the thickness T2 of the low refractive-index portion 40 to the length of one side of the top surface of the base portion 31 of the optical functional unit 30 is 5%, the narrow-angle luminous flux amount ratio was 138% and the largest.

Accordingly, it was found that in the light-emitting device 1 of Embodiment 1, the thickness T2 of the low refractive-index portion 40 preferable to increase the narrow-angle luminous flux amount ratio of the light extracted from the light-emitting surface of the optical functional unit 30 is in a range of 0.1% or more and 20% or less, and especially in a range of 0.1% or more and 10% or less with respect to the length of one side of the top surface of the base portion 31 of the optical functional unit 30.

That is, when the base portion 31 of the optical functional unit 30 has the square outer shape having one side of 1.0 mm, the thickness T2 of the low refractive-index portion 40 preferable to increase the narrow-angle luminous flux amount ratio of the light extracted from the light-emitting surface of the optical functional unit 30 is in a range of 0.001 mm or more and 0.2 mm or less, especially in a range of 0.001 mm or more and 0.1 mm or less.

### (Verification of Thickness of Base Portion of Optical Functional Unit)

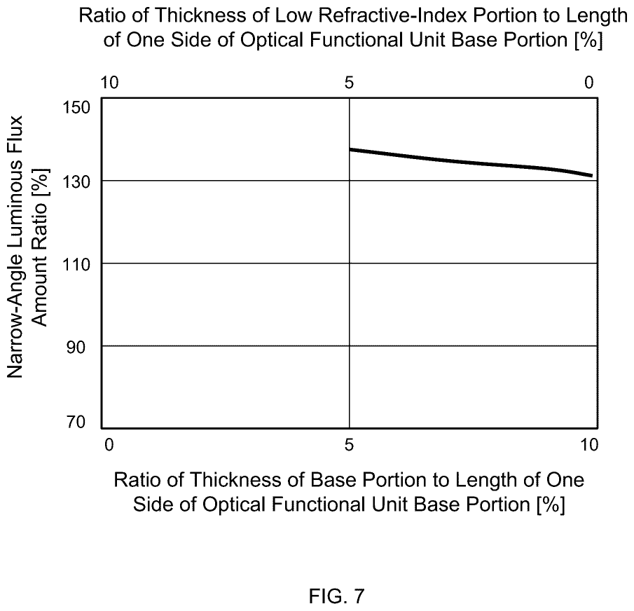

FIG. 7 is a drawing illustrating a simulation result of the luminous flux amount ratio of the narrow-angle component of the light emitted from the light-emitting device 1 when the thickness T1 of the base portion 31 of the optical functional unit 30 is changed.

In FIG. 7, the simulation was performed with a ratio of a total thickness of the thickness T1 of the base portion 31 and the thickness T2 of the low refractive-index portion 40 set to 10% with respect to the length of one side of the top surface of the base portion 31 of the optical functional unit 30 based on the simulation result illustrated in FIG. 6. The other structure of the light-emitting device 1 is similar to the structure described in FIG. 6.

The lower horizontal axis of FIG. 7 indicates a ratio of the thickness T1 of the base portion 31 to the length of one side of the top surface of the base portion 31 of the optical functional unit 30. The upper vertical axis of FIG. 7 indicates the ratio of the thickness T2 of the low refractive-index portion 40 to the length of one side of the top surface of the base portion 31 of the optical functional unit 30.

In FIG. 7, the simulation was performed by varying the ratio of the thickness T1 of the base portion 31 to the length of one side of the top surface of the base portion 31 of the optical functional unit 30 from 5% to 10%. That is, in association with the variation of the ratio of the thickness T1 of the base portion 31, the ratio of the total thickness of the thickness T2 of the low refractive-index portion 40 to the length of one side of the top surface of the base portion 31 of the optical functional unit 30 varies from 5% to 0%.

The vertical axis of FIG. 7 indicates the luminous flux amount ratio in a narrow angle range (+30°) when the ratio of the thickness T1 of the base portion 31 is changed. On the vertical axis of FIG. 7, similarly to FIG. 6, the amount of luminous flux in a narrow angle of a light-emitting device that is not provided with the optical functional unit 30 and emits a light having a directivity of the ideal Lambertian orientation from the top surface of the wavelength conversion member is assumed to be 100%. In the light-emitting device that emits the light having the directivity of the ideal Lambertian orientation, the top surface shape of the wavelength conversion member is set to a square having one side of 1.0 mm.

As illustrated in FIG. 7, in the entire range of 5 to 10% of the ratio of the thickness T1 of the base portion 31 of the optical functional unit 30, which is the simulation range, the narrow-angle luminous flux amount ratio was 130% or more.

At a position at which the ratio of the thickness T1 of the base portion 31 of the optical functional unit 30 is 5%, the narrow-angle luminous flux amount ratio was 138%, and had the maximum value. It was found that in accordance with the increase of the thickness T1 of the base portion 31 of the optical functional unit 30 from 5%, the narrow-angle luminous flux amount ratio tends to decrease.

Accordingly, in the light-emitting device 1 of Embodiment 1, the thickness T1 of the base portion 31 preferable to increase the narrow-angle luminous flux amount ratio of the light extracted from the light-emitting surface of the optical functional unit 30 may be any thickness insofar as the thickness T1 of the base portion 31 is in a range of 5% or more and 10% or less with respect to the length of one side of the top surface of the base portion 31 of the optical functional unit 30, which is the range on which the simulation was performed.

It was found that in the range on which the simulation was performed, when the ratio of the thickness T1 of the base portion 31 is 5%, that is, the thickness similar to the thickness T2 of the low refractive-index portion 40, it is most effective for the narrow-angle luminous flux amount ratio.

### (Verification of Projection Radius of Optical Functional Unit)

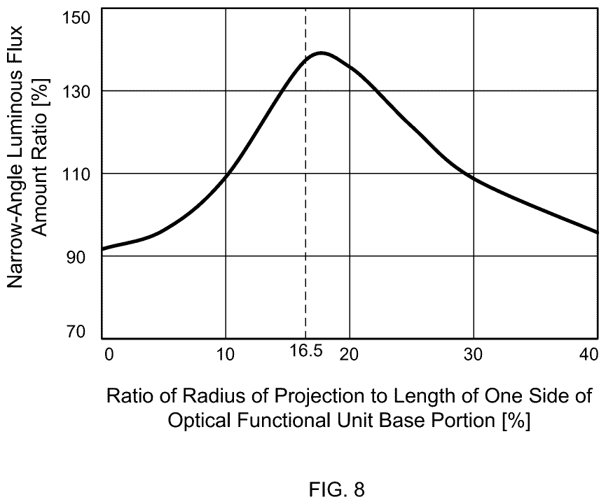

FIG. 8 is a graph illustrating a simulation result of the narrow-angle luminous flux amount ratio of the light-emitting device 1 when the radius R1 of the projection 32 is varied in the case where the nine projections 32 in total are arranged in a matrix of three rows and three columns on the top surface of the base portion 31 of the optical functional unit 30 in Embodiment 1.

The horizontal axis of FIG. 8 indicates a ratio of the radius R1 of the projection 32 to the length of one side of the top surface of the base portion 31 of the optical functional unit 30. In FIG. 8, the simulation was performed by varying the ratio of the radius R1 of the projection 32 to the length of one side of the top surface of the base portion 31 of the optical functional unit 30 from 0% to 40%. That is, a state where the projection 32 is not formed at a position at which the ratio of the radius R1 of the projection 32 is 0% in the optical functional unit 30 is illustrated. When the ratio of the radius R1 of the projection 32 is 16.5% or more, the projections 32 adjacent in the X and Y directions overlap with each other in top view. At 23.6% or more, the projections 32 adjacent in a diagonal direction of the top surface of the base portion 31 overlap with each other.

The vertical axis of FIG. 8 indicates the luminous flux amount ratio in a narrow angle range (±30°) when the ratio of the radius R1 of the projection 32 is changed. On the vertical axis of FIG. 8, the amount of luminous flux in a narrow angle of a light-emitting device that is not provided with the optical functional unit 30 and emits a light having a directivity of the ideal Lambertian orientation from the top surface of the wavelength conversion member is assumed to be 100%. In the light-emitting device that emits the light having the directivity of the ideal Lambertian orientation, the top surface shape of the wavelength conversion member is set to a square having one side of 1.0 mm.

As illustrated in FIG. 8, in a range in which the ratio of the radius R1 of the projection 32 is 10% or more and 30% or less, the narrow-angle luminous flux amount ratio was 110% or more. In a range in which the ratio of the radius R1 of the projection 32 is 15% or more and 22% or less, the narrow-angle luminous flux amount ratio was 130% or more. At a position at which the ratio of the radius R1 of the projection 32 is 17.5%, the narrow-angle luminous flux amount ratio was 139%, and had the maximum value.

From the simulation result of FIG. 8, it was found to be most effective for a narrow angle performance of the optical functional unit 30 to form the projection 32 with the radius R1 that is a dimension at which the projections 32 adjacent in the X and Y directions partially overlap with each other and the projections 32 adjacent in the diagonal direction of the top surface of the base portion 31 do not overlap with each other in top view.

In other words, it was found that an exposed area of a flat surface as the top surface of the base portion 31 at the top surface of the optical functional unit 30 is preferred to be small. Further, it was found to be preferable that the adjacent projections 32 do not overlap with each other to the extent that a hemisphere surface as a surface of the projection 32 does not impair the lens effect.

### (Verification of the Number of Projections to Be Arranged of Optical Functional Unit)

In Embodiment 1, the case where the nine projections 32 in total are arranged in a matrix of three rows and three columns on the top surface of the base portion 31 of the optical functional unit 30 is described. However, the number of the projections 32 to be arranged of the optical functional unit 30 is not limited to this.

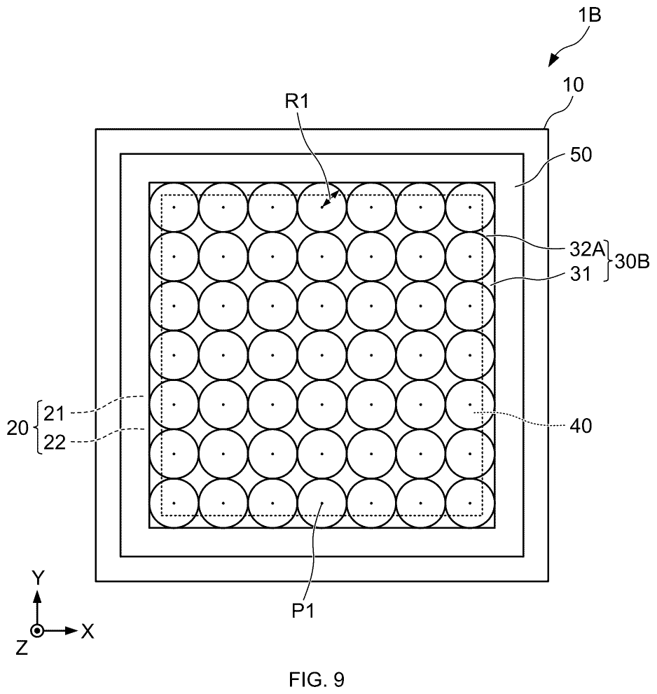

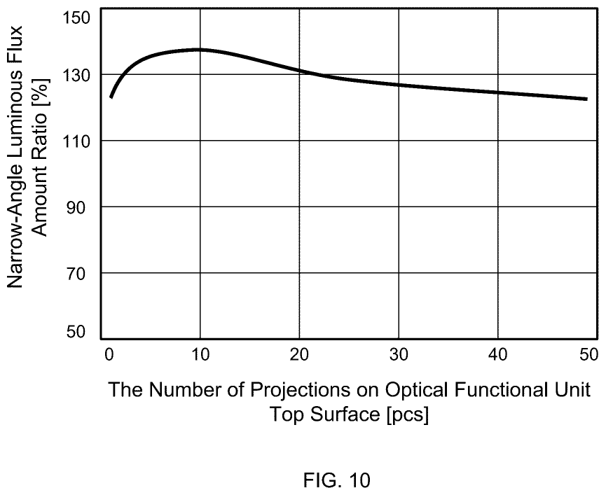

FIG. 9 and FIG. 10 are drawings for describing a simulation of the narrow-angle luminous flux amount ratio when the number of the projections 32 to be arranged in a matrix on the top surface of the base portion 31 of the optical functional unit 30 is a different number.

In this simulation, the simulation was performed with the number of the projections 32 to be arranged on the top surface of the base portion 31 of the optical functional unit 30 varied from one row and one column to seven rows and seven columns.

For the radius R1 of the projection 32 in this simulation, center points P1 of respective compartments are arranged as center points of the respective projections 32 when the top surface of the base portion 31 of the optical functional unit 30 is equally divided into compartments of one row and one column (one compartment in total) to seven rows and seven columns (49 compartments in total) in the X and Y directions.

The simulation was performed assuming that each of the projections 32 has the radius R1 that reaches the end portion of each compartment having the center point P1 as the center. That is, when one projection 32 is formed in the compartment of one row and one column, the radius of the projection 32 has the radius R1 that is 50% with respect to the length of one side of the top surface of the base portion 31 of the optical functional unit 30, and when 49 projections 32 are formed in the compartments of seven rows and seven columns, the radius of the projection 32 has the radius R1 that is about 7.1% with respect to the length of one side of the top surface of the base portion 31 of the optical functional unit 30. Therefore, this simulation is a simulation of the case where the adjacent projections 32 do not overlap with each other in top view.

FIG. 9 is a drawing illustrating a top view of a light-emitting device 1B, for example, when the 49 projections 32 are formed in the compartments of seven rows and seven columns.

FIG. 10 is a graph illustrating a simulation result of the narrow-angle luminous flux amount ratio of the light-emitting device 1B when the radius R1 of the projection 32 is varied in the case where the nine projections 32 in total are arranged in a matrix of three rows and three columns on the top surface of the base portion 31 of the optical functional unit 30.

The horizontal axis of FIG. 10 indicates the total number of the projections 32 when the number of the projections 32 to be arranged on the top surface of the base portion 31 of the optical functional unit 30 is varied from one row and one column to seven rows and seven columns.

The vertical axis of FIG. 10 indicates the luminous flux amount ratio in a narrow angle range (+30°) when the number of the projections 32 to be arranged is changed. On the vertical axis of FIG. 10, the amount of luminous flux in a narrow angle of a light-emitting device that is not provided with the optical functional unit 30 and emits a light having a directivity of the ideal Lambertian orientation from the top surface of the wavelength conversion member is assumed to be 100%. In the light-emitting device that emits the light having the directivity of the ideal Lambertian orientation, the top surface shape of the wavelength conversion member is set to a square having one side of 1.0 mm.

As illustrated in FIG. 10, in any simulation range of the number of the projections 32 to be arranged, the narrow-angle luminous flux amount ratio was 110% or more. At positions at which the number of the projections 32 to be arranged is four (two rows and two columns), nine (three rows and three columns), and 16 (four rows and four columns), the narrow-angle luminous flux amount ratio was 130% or more. At the position at which the number of the projections 32 to be arranged is nine (three rows and three columns), the narrow-angle luminous flux amount ratio was 137%, and had the maximum value.

From the simulation result of FIG. 10, it was found that the case where the nine projections 32 in total are arranged in a matrix of three rows and three columns on the top surface of the base portion 31 of the optical functional unit 30 is most effective for the narrow angle performance of the optical functional unit 30.

### (Verification of Adding Second Projection of Optical Functional Unit)

In Embodiment 1, the case where the projections 32 having the same shape are arranged in a matrix on the top surface of the base portion 31 of the optical functional unit 30 is described. However, the arrangement structure of the projection 32 of the optical functional unit 30 is not limited to this.

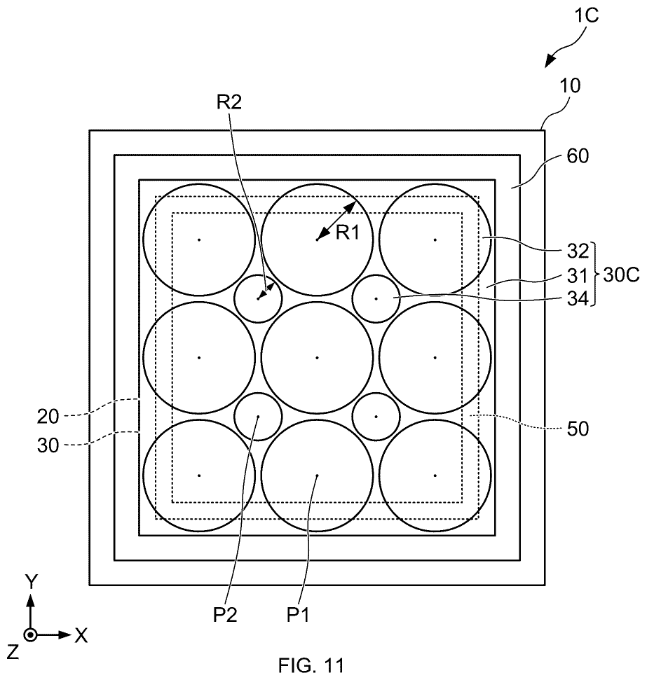

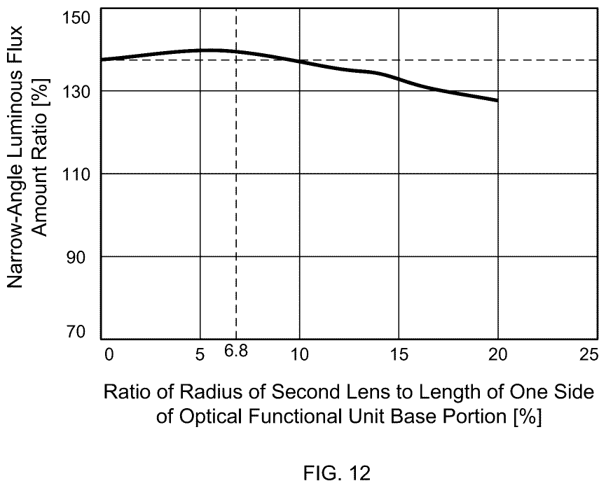

FIG. 11 and FIG. 12 are drawings of a simulation of the narrow-angle luminous flux amount ratio when first projections 32 are arranged in a matrix on the top surface of the base portion 31 of the optical functional unit 30 and second projections 34 are arranged in gap regions between the first projections 32 on the top surface of the base portion 31.

In other words, the projections of the optical functional unit 30 of the light-emitting device 1 may have a structure that includes the first projections 32 arranged in a matrix on the base portion and the second projections 34 each arranged in the region between the rows and between the columns of the matrix arrangement of the first projections 32.

In this simulation, similarly to Embodiment 1, the first projections 32 are arranged in a matrix in a manner of three rows and three columns with the radius R1 of 16.5% with respect to the length of one side of the top surface of the base portion 31 of the optical functional unit 30 on the top surface of the base portion 31 of the optical functional unit 30. The second projection 34 is formed in a hemispherical shape with a radius R2 at a center point P2 of the gap region between the first projections 32.

In this simulation, the drawing illustrates the simulation of the narrow-angle luminous flux amount ratio of a light-emitting device 1C when the radius R2 of the second projection 34 is varied.

FIG. 11 is a drawing illustrating a top view of the light-emitting device 1C, for example, in which the second projections 34 are arranged in a matrix in a manner of three rows and three columns in the gap regions between the first projections 32 when the first projections 32 are arranged in a matrix in a manner of three rows and three columns.

FIG. 12 is a drawing illustrating the simulation of the narrow-angle luminous flux amount ratio of the light-emitting device 1C when the radius R2 of the second projection 34 is varied. The ratio of the radius R1 of the first projection 32 was fixed to 16.5% similarly to Embodiment 1.

The horizontal axis of FIG. 12 indicates a ratio of the radius R2 of the second projection 34 to the length of one side of the top surface of the base portion 31 of the optical functional unit 30. In FIG. 12, the simulation was performed by varying the ratio of the radius R2 of the second projection 34 to the length of one side of the top surface of the base portion 31 of the optical functional unit 30 from 0% to 20%. That is, a state where the second projection 34 is not formed at the optical functional unit 30 at a position at which the ratio of the radius R2 of the second projection 34 is 0%, and only the first projection 32 contributes to narrow the angle of the emitted light from the light-emitting device 1C is illustrated. When the ratio of the radius R2 of the second projection 34 is about 6.8% or more, the second projection 34 overlaps with the mutually adjacent first projections 32 in top view.

The vertical axis of FIG. 12 indicates the luminous flux amount ratio in a narrow angle range (±30°) when the ratio of the radius R2 of the second projection 34 is changed. On the vertical axis of FIG. 12, the amount of luminous flux in a narrow angle of a light-emitting device that is not provided with the optical functional unit 30 and emits a light having a directivity of the ideal Lambertian orientation from the top surface of the wavelength conversion member is assumed to be 100%. In the light-emitting device that emits the light having the directivity of the ideal Lambertian orientation, the top surface shape of the wavelength conversion member is set to a square having one side of 1.0 mm.

As illustrated in FIG. 12, in a range in which the ratio of the radius R2 of the second projection 34 is 0% or more and 17.3% or less, the narrow-angle luminous flux amount ratio was 130% or more. At a position at which the ratio of the radius R2 of the second projection 34 is about 6%, the narrow-angle luminous flux amount ratio was 140%, and had the maximum value.

In a range in which the ratio of the radius R2 of the second projection 34 is about 8% or more, the narrow-angle luminous flux amount ratio had a tendency of decrease compared with the case where the second projection 34 is not formed (the ratio of the radius R2 of the second projection 34 is 0%).

From the simulation result of FIG. 12, it is considered to be effective for improving the narrow angle performance of the optical functional unit 30 to form the second projection 34 not to overlap with the first projection 32 in top view.

### Modifications

The following describes modifications of the light-emitting device 1 according to Embodiment 1 of the present invention.

### (Modification 1)

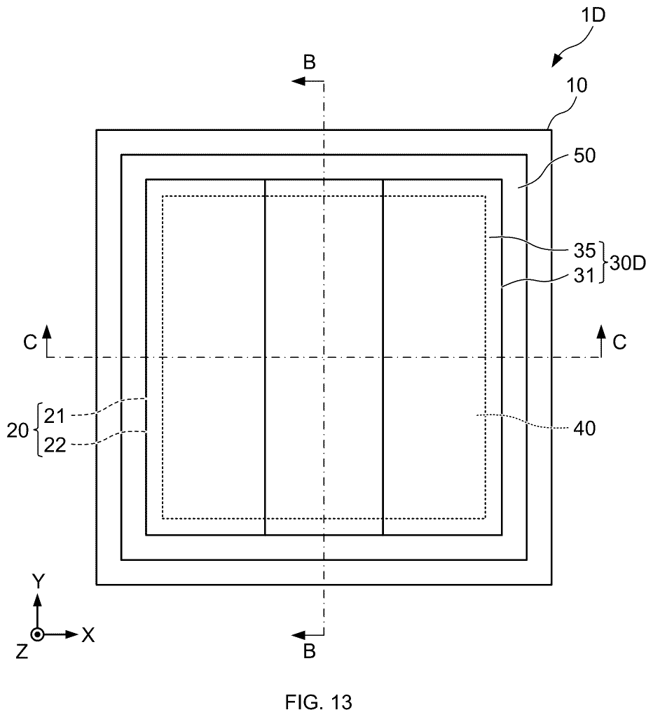

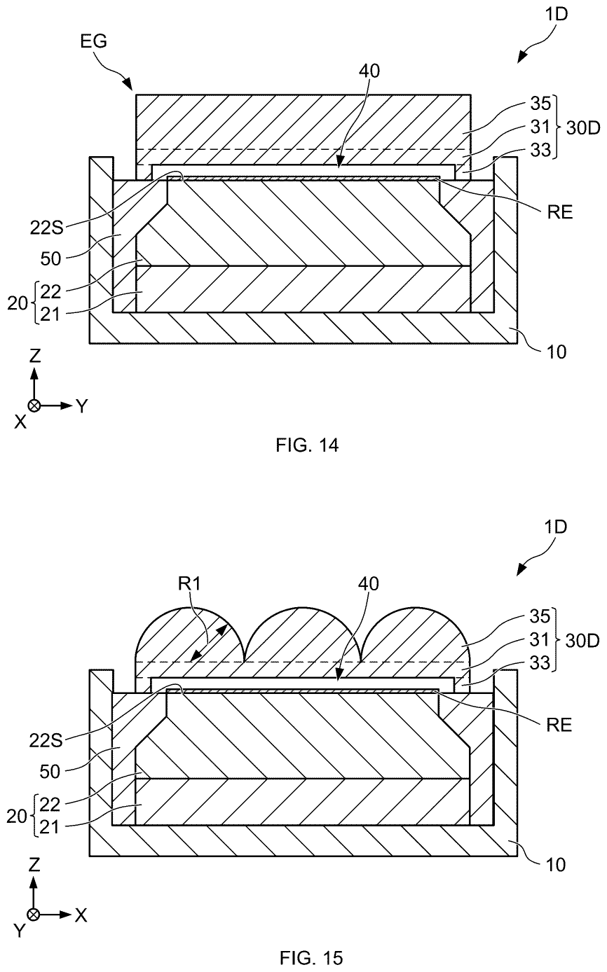

FIG. 13 is a top view of a light-emitting device 1D according to Modification 1. FIG. 14 is a cross-sectional view of the light-emitting device 1 taken along a line B-B illustrate in FIG. 13. FIG. 15 is a cross-sectional view of the light-emitting device 1 taken along a line C-C illustrate in FIG. 13.

The light-emitting device 1D of Modification 1 has a configuration basically similar to the light-emitting device 1 of Embodiment 1. The light-emitting device 1D of Modification 1 is different from Embodiment 1 in that a projection 35 formed on the top surface of the base portion 31 of an optical functional unit 30D has a semi-cylindrical shape projecting upward and extending to both end portions of a pair of opposed sides of the top surface of the base portion 31. That is, the projection 35 is a cylindrical lens formed on the top surface of the base portion 31 of the optical functional unit 30D.

In this embodiment 1, as illustrated in FIG. 13 and FIG. 14, the projection 35 is a cylindrical lens having a surface along a pair of sides parallel to the Y-direction of the top surface of the base portion 31 of the optical functional unit 30D as a bottom surface and extending in the Y-direction.

In this embodiment 1, as illustrated in FIG. 15, the projection 35 has a semicircle having the radius R1 from the top surface of the base portion 31 of the optical functional unit 30D as a bottom surface. In this embodiment 1, the radius R1 of the bottom surface of the projection 35 is set to 16.5% with respect to a length of one side of the top surface of the base portion 31 of the optical functional unit 30D. The projections 35 are arranged as three cylindrical lenses in the X-direction on the top surface of the base portion 31.

By forming the semi-cylindrical cylindrical lenses on the top surface of the base portion 31 of the optical functional unit 30D, the directivity in the X and Y directions can be controlled. For example, it is effective when the emitted light from the light-emitting device ID needs to be narrowed in angle only in the X-direction.

The projection 35 may be extended in the X-direction. A corner portion EG of the cylindrical lens illustrated in FIG. 14 may be chamfered by R processing or the like.

In the light-emitting device 1D, when the emitted light needs to be controlled individually in the X-direction and the Y-direction, the projection 35 is not limited to the cylindrical lens, and an elliptical lens, an aspheric lens, and the like may be used. The projection 35 may have a conical shape or a frustum shape. In this case, the projections 35 may be arranged in a matrix on the base portion 31 as in Embodiment 1.

### (Modification 2)

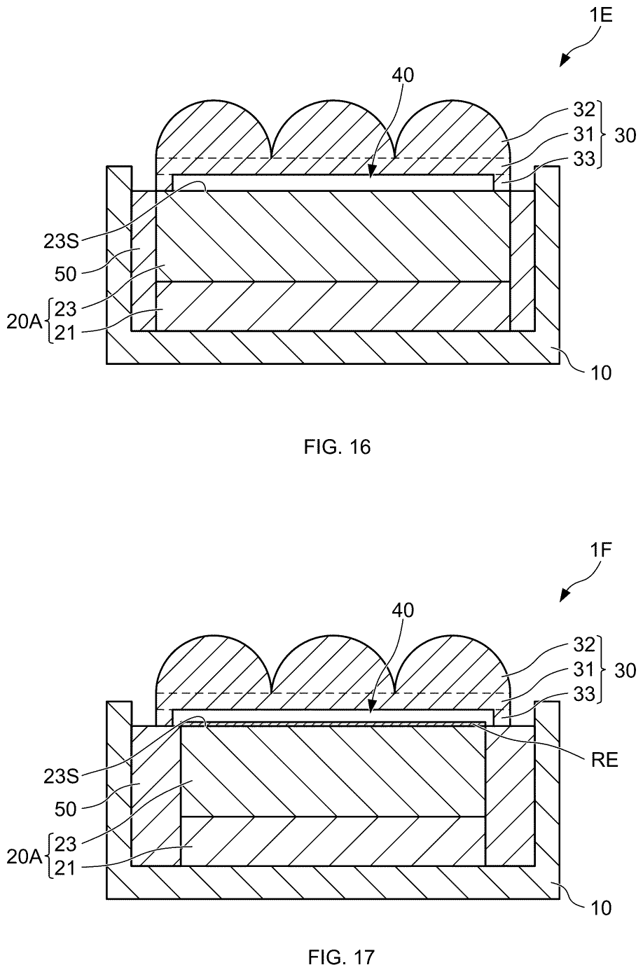

As illustrated in FIG. 16, a light-emitting device 1E according to Modification 2 may include a wavelength conversion member 23 of a light-emitting portion 20A formed in a columnar shape without an inclined side surface at a side surface.

In this case, when the top surface shape (light-emitting region) of the semiconductor light-emitting element 21 is a square having the length D1 of one side of 1.0 mm, the top surface shape of the wavelength conversion member 23 is also a square having the length D2 of one side of 1.0 mm. Therefore, in the light-emitting device 1E, in top view, respective outer surfaces of the optical functional unit 30 mounted on the wavelength conversion member 23, the wavelength conversion member 23, and the semiconductor light-emitting element 21 are approximately matched.

As in the light-emitting device 1E according to Modification 2, the spacer portion 33 of the optical functional unit 30 can be joined to a top surface 23S along an outer edge of the top surface 23S of the wavelength conversion member 23.

In the light-emitting device 1E according to Modification 2, in top view, an outer edge of a top surface of the light-emitting portion 20A (that is, the outer edge of the top surface of the wavelength conversion member 23) is positioned at outer edges of the projections 32 arranged at the outermost periphery and an outer edge of the optical functional unit 30. That is, in Embodiment 1, in top view, an outer edge end portion of the optical functional unit 30 is positioned outside with respect to the outer edge of the top surface of the light-emitting portion 20 (that is, the outer edge of the top surface of the wavelength conversion member 22) in top view. Therefore, the shape of the light source image projected from the light-emitting device 1E can be made significantly similar to the top surface shape of the light-emitting portion 20A.

The light emitted from a region excluding the region in which the spacer portion 33 of the top surface 23S of the wavelength conversion member 23 is joined is, similarly to Embodiment 1, incident on the lower surface of the base portion 31 of the optical functional unit 30 via the low refractive-index portion 40. Therefore, the light-emitting device 1E can narrow the angle of the emitted light.

As described in Embodiment 1, the spacer portion 33 of the optical functional unit 30 is formed to have a narrow width of about 50 μm. Therefore, a large part of the light incident on the spacer portion 33 from the top surface 23S of the wavelength conversion member 23 is totally reflected by the side surface inside the spacer portion 33, guided to the projection 32, and emitted from the surface of the projection 32 as a light within the narrow angle range with a high probability.

In the light-emitting device 1E, for example, the spacer portion 33 and the wavelength conversion member 23 can be joined to each other by an appropriate method, such as a surface activated bonding, without the transparent adhesive.

For example, a flat plate-shaped silicone resin body with the spacer portion 33 formed in a grid pattern on the lower surface is joined to an alumina material containing phosphor particles on a flat plate by the surface activated bonding. At this time, on a surface to be joined to the silicone resin body of the alumina material, a bonding film (not illustrated) of silicon oxide (SiO₂) film or the like for the surface activated bonding is formed.

After the surface activated bonding of the alumina material and the silicone resin body, for example, the projections 32 are formed on a top surface of the silicone resin body using an imprint method. By individualizing this by dicing and the like, composites of the wavelength conversion member 23 and the optical functional unit 30 joined in advance are obtained. Joining the composites on the semiconductor light-emitting element 21 allows simplifying the manufacturing process of the light-emitting device 1E.

By joining the spacer portion 33 formed along the outer edge of the lower surface of the base portion 31 to the outer edge of the top surface 23S of the wavelength conversion member 23 by the surface activated bonding, the low refractive-index portion 40 is formed as an airtight space provided by the optical functional unit 30 and the wavelength conversion member 23.

As a result, when the raw material resin of the light reflecting member 50 is filled into the recess of the substrate 10, it is possible to keep the raw material resin from creeping up onto the top surface 22S of the wavelength conversion member 22. Accordingly, it is also possible to omit the formation of the coating layer RE, such as a fluorine film or the like having low affinity with the resin material, on the top surface 23S of the wavelength conversion member 23.

### (Modification 3)

As illustrated in FIG. 17, a light-emitting device 1F according to Modification 3 may have an outer edge shape of the optical functional unit 30 larger than an outer edge shape of the semiconductor light-emitting element 21 and the wavelength conversion member 23 of the light-emitting portion 20A in top view.

The light emitted from the top surface 23S of the wavelength conversion member 23 is, similarly to Embodiment 1, incident on the lower surface of the base portion 31 of the optical functional unit 30 via the low refractive-index portion 40. Accordingly, the light-emitting device 1F can narrow the angle of the emitted light.

In this case, the spacer portion 33 of the optical functional unit 30 is joined to the top surface of the light reflecting member 50. Therefore, the manufacturing method for the light-emitting device 1F is a manufacturing method similar to that of the light-emitting device 1 according to Embodiment 1.

In the light-emitting device 1F, the length of one side of the outer edge of the base portion 31 of the optical functional unit 30 may be increased, or the length of one side of the outer edge of the semiconductor light-emitting element 21 and the wavelength conversion member 23 may be decreased.

As described for the light-emitting device 1E of Modification 2 and the light-emitting device 1F of Modification 3, for the lower surface of the spacer portion 33 of the optical functional unit 30, the lower surface of the spacer portion 33 may be in contact with both the top surface 22S of the wavelength conversion member 22 and the top surface of the light reflecting member 50 without limiting to only one of the top surface 22S of the wavelength conversion member 22 or the top surface of the light reflecting member 50. In other words, in top view, the lower surface of the spacer portion 33 may be at least partially overlapped with the top surface 22S of the wavelength conversion member 22 of the light-emitting portion 20.

### (Modification 4)

As illustrated in FIG. 18, a light-emitting device 1G according to Modification 4 may have the outer edge shape of the optical functional unit 30 smaller than the outer edge shape of the semiconductor light-emitting element 21 and the wavelength conversion member 23 of the light-emitting portion 20A in top view.

In this case, it is only necessary to increase an inclined angle of the inclined surface of the side surface of the wavelength conversion member 22 to make the outer edge shape of the top surface 22S of the wavelength conversion member 22 equal to or smaller than the outer edge shape of the optical functional unit 30 in top view.

The light emitted from the top surface 22S of the wavelength conversion member 22 is, similarly to Embodiment 1, incident on the lower surface of the base portion 31 of the optical functional unit 30 via the low refractive-index portion 40. Accordingly, the light-emitting device 1G can narrow the angle of the emitted light.

By increasing a size difference between the lower surface and the top surface 22S of the wavelength conversion member 22, a light condensing action of the wavelength conversion member 22 is improved, that is, the total luminous flux amount of the emitted light from the light-emitting device 1G can be increased.

From the description of the light-emitting device 1E of Modification 2 and the light-emitting device 1F of Modification 3, the outer edge shape of the optical functional unit 30 only needs to have a size equal to or more than that of the top surface 22S of the wavelength conversion member 22 in top view.

When the outer edge shape of the optical functional unit 30 is larger than the top surface 22S of the wavelength conversion member 22 in top view, that is, when the spacer portion 33 of the optical functional unit 30 is provided on the top surface of the light reflecting member 50, the manufacturing method for the light-emitting device 1G is similar to the manufacturing method for the light-emitting device 1 according to Embodiment 1.

When the outer edge shape of the optical functional unit 30 is approximately same as the top surface 22S of the wavelength conversion member 22 in top view, that is, when the spacer portion 33 of the optical functional unit 30 is provided in the region along the outer edge of the top surface 22S of the wavelength conversion member 22, forming the coating layer RE of the fluorine film or the like may be omitted, and the spacer portion 33 of the optical functional unit 30 may be joined to the top surface 22S of the wavelength conversion member 22 by the surface activated bonding.

In the light-emitting device 1G, the outer edge shapes of the top surface 22S of the wavelength conversion member 22 and the optical functional unit 30 in top view may be each decreased, or the outer edge shape of the semiconductor light-emitting element 21 in top view and the lower surface of the wavelength conversion member 23 may be each decreased.

### (Modification 5)

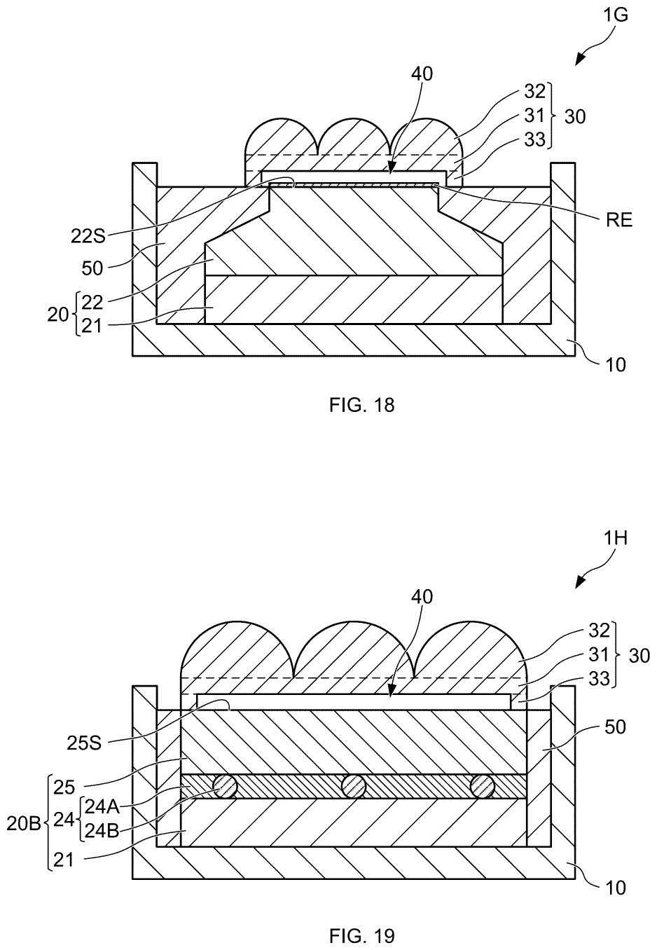

As illustrated in FIG. 19, a light-emitting device 1H according to Modification 5 may include a wavelength conversion member 24, which performs wavelength conversion of the light emitted from the semiconductor light-emitting element 21, made of another material and the like.

A light-emitting portion 20B of the light-emitting device 1H according to Modification 5 includes the wavelength conversion member 24 containing a wavelength conversion resin 24A on the semiconductor light-emitting element 21 and spherical particles 24B dispersed in the wavelength conversion resin 24A, and a transparent member 25 disposed on the wavelength conversion member 24.

The wavelength conversion resin 24A is made of, for example, a transparent thermosetting resin, such as a silicone resin containing YAG:Ce phosphor particles. The spherical particles 24B are made of, for example, glass beads or silicone resin particles, and dispersed in the wavelength conversion resin 24A.

For example, the transparent member 25 has a top surface 25S as the light-emitting surface, and is made of a transparent material, such as a silicate glass plate. The lower surface of the transparent member 25 as a light incident surface is joined to the top surface of the semiconductor light-emitting element 21 with the thermosetting resin contained in the wavelength conversion resin 24A.

The spherical particles 24B function as a spacer that separates the top surface of the semiconductor light-emitting element 21 and the lower surface of the transparent member 25 by a predetermined distance.

The light-emitting device 1H can narrow the angle of the emitted light emitted from the light-emitting device 1H with the reason similar to that described in Modification 2.

The spacer portion 33 of the optical functional unit 30 and the top surface 25S of the transparent member 25 may be joined by the surface activated bonding, thereby obtaining a composite of the transparent member 25 and the optical functional unit 30. By using the silicate glass plate for the transparent member 25, for example, forming a bonding film of a silicon oxide (SiO2) film or the like for performing the surface activated bonding on the surface of the transparent member 25 on which the surface activated bonding with the optical functional unit 30 is performed can be omitted. Accordingly, the manufacturing method for the light-emitting device 1H can be simplified.

In the manufacturing method for the light-emitting device 1H, for example, after joining the semiconductor light-emitting element 21 to the recess bottom surface of the substrate 10, a precursor of the wavelength conversion resin 24A in which the spherical particles 24B are dispersed is applied over the top surface of the semiconductor light-emitting element 21. Then, the above-described composite of the transparent member 25 and the optical functional unit 30 is placed so as to be in contact with the precursor of the wavelength conversion resin 24A applied over the semiconductor light-emitting element 21, and heated to thermally cure the precursor of the wavelength conversion resin 24A, thereby allowing the manufacture.

In the light-emitting device 1H, the outer edge shape of the optical functional unit 30 may be larger than the transparent member 25 in top view. That is, the spacer portion 33 of the optical functional unit 30 may be provided on the top surface of the light reflecting member 50.

### (Modification 6)

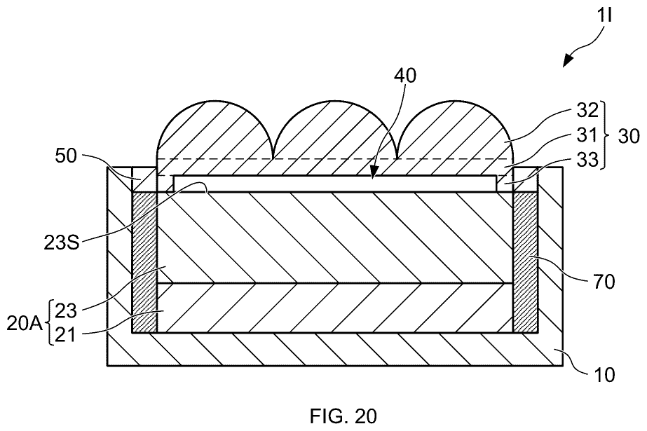

As illustrated in FIG. 20, in a light-emitting device 1I according to Modification 6, the side surface of the semiconductor light-emitting element 21 and the wavelength conversion member 22 may be covered with a light guide portion 70 made of a light transmissive resin, and the light reflecting member 50 may be formed on a top surface of the light guide portion 70.

In this case, the light reflecting member 50 is preferably formed to cover an outer surface of the spacer portion 33 and a region of a part of the side surface from the lower end of the base portion 31 of the optical functional unit 30.

This allows the light-emitting device 1I to block the light and the like from the outer surface of the spacer portion 33 and the side surface of the base portion 31 of the optical functional unit 30 and suppress emission of the light from an unintended part of the light-emitting device 1I.

### (Modification 7)

As illustrated in FIG. 21, in a light-emitting device 1J according to Modification 7, when the wavelength conversion of the light emitted from the semiconductor light-emitting element 21 is not performed, the wavelength conversion member 22 does not need to be disposed.

As illustrated in FIG. 21, in the light-emitting device 1J, the outer edge shape of the optical functional unit 30 approximately matches the outer edge of a top surface 21S of the semiconductor light-emitting element 21 in top view. That is, the spacer portion 33 of the optical functional unit 30 is provided on the top surface 21S of the semiconductor light-emitting element 21.

The light-emitting device 1J can narrow the angle of the emitted light emitted from the light-emitting device 1J with the reason similar to that described in Modification 2.

The top surface 21S of the semiconductor light-emitting element 21 and the lower surface of the spacer portion 33 of the optical functional unit 30 can be joined by the surface activated bonding.

For example, a flat plate-shaped silicone resin body with the spacer portion 33 formed in a grid pattern on the lower surface can be joined to a group of semiconductor light-emitting elements 21 in a wafer state by the surface activated bonding.

Usually, a sapphire (Al₂O₃) substrate is used for a growth substrate that is a top surface side of the flip-chip type semiconductor light-emitting element 21. Therefore, the top surface 21S of the group of semiconductor light-emitting elements 21 in the wafer state can be directly joined with the silicone resin body by the surface activated bonding without forming a bonding film of a silicon oxide (SiO₂) film or the like for performing the surface activated bonding.

When the semiconductor light-emitting element 21 that includes the support substrate without the translucency and the semiconductor structure layer provided in one region on the top surface of the support substrate is used, usually, a silicon oxide (SiO₂) film is formed on the top surface 21S including the semiconductor structure layer of the semiconductor light-emitting element 21 as a protective film. Accordingly, the top surface 21S including the semiconductor structure layer of the semiconductor light-emitting element 21 also can be joined to the silicone resin body by the surface activated bonding.

### (Modification 8)

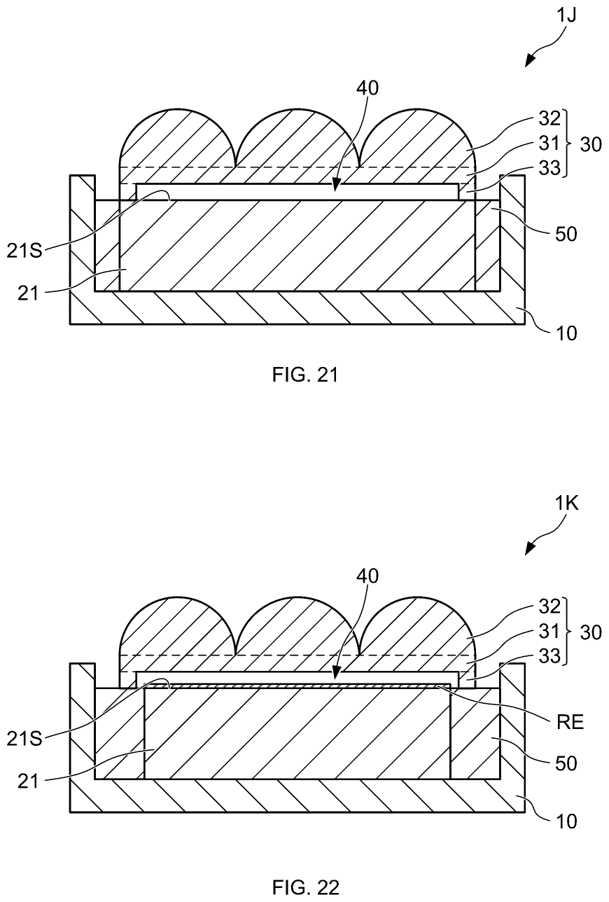

As illustrated in FIG. 22, in a light-emitting device 1K according to Modification 8, the outer edge shape of the optical functional unit 30 may be larger than the outer edge shape of the top surface 21S of the semiconductor light-emitting element 21 in top view.

The light emitted from the top surface 21S of the semiconductor light-emitting element 21 is, similarly to Embodiment 1, incident on the lower surface of the base portion 31 of the optical functional unit 30 via the low refractive-index portion 40. Accordingly, the light-emitting device 1K can narrow the angle of the emitted light.

In the light-emitting device 1J of Modification 7 and the light-emitting device 1K of Modification 8, a glass plate may be disposed on the top surface of the semiconductor light-emitting element 21 as in the light-emitting device 1H of Modification 5.

### (Modification 9)

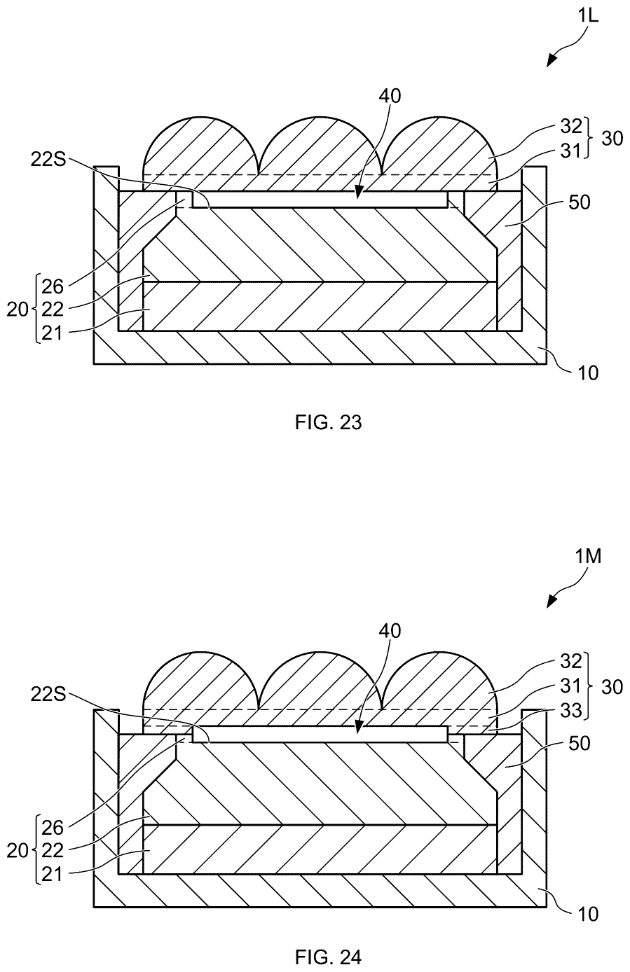

As illustrated in FIG. 23, in a light-emitting device 1L according to Modification 9, a spacer portion for forming the low refractive-index portion 40 may be integrally formed on the top surface 22S with the wavelength conversion member 22. In the light-emitting device 1L according to Modification 9, since a space for forming the low refractive-index portion 40 can be formed by processing the wavelength conversion member 22, the low refractive-index portion 40 can be stably provided in shape, size, and thickness.

In the light-emitting device 1L of Modification 9, a spacer portion 26 protruding upward is formed in a region along the outer edge of the top surface 22S of the wavelength conversion member 22. That is, the spacer portion 33 is a protruding portion protruding upward from the top surface 22S of the wavelength conversion member 22 of the light-emitting portion 20.

The spacer portion 33 is not integrally formed on the lower surface of the base portion 31 of the optical functional unit 30, and the lower surface of the optical functional unit 30 is a planar surface configured of only the lower surface of the base portion 31.

For example, the spacer portion 26 of the wavelength conversion member 22 is formed to have a width of about 50 μm similarly to the spacer portion 33 of Embodiment 1. A height of the spacer portion 26 of the wavelength conversion member 22 is preferably formed in a manner in which the thickness T of the low refractive-index portion 40 is in a range of 0.1% or more and 20% or less, especially in a range of 0.1% or more and 10% or less with respect to the length of one side of the top surface of the base portion 31 of the optical functional unit 30, as described in FIG. 6.

As illustrated in FIG. 23, the light reflecting member 50 is formed up to the upper end of the outer surface of the spacer portion 26 of the wavelength conversion member 22. That is, the spacer portion 26 of the wavelength conversion member 22 is supported by the light reflecting member 50. This enhances the rigidity of the spacer portion 26 of the wavelength conversion member 22, thus allowing suppressing the damage on the spacer portion 26 due to a stress by thermal expansion at driving of the light-emitting device 1L, vibration from outside, or the like.

Furthermore, since the lower surface of the optical functional unit 30 is a planar surface, the lower surface of the optical functional unit 30 is in contact with a region from the top surface of the spacer portion 26 of the wavelength conversion member 22 to the top surface of the light reflecting member 50. This increases a bonding region of the lower surface of the optical functional unit 30 to the top surface of the spacer portion 26 of the wavelength conversion member 22 and the top surface of the light reflecting member 50, thus allowing enhancing the bonding strength of the optical functional unit 30.

### (Modification 10)

As illustrated in FIG. 24, in a light-emitting device 1M according to Modification 10, a spacer portion for forming the low refractive-index portion 40 may be formed on both the lower surface of a base portion 31B of the optical functional unit 30 and the top surface 22S of the wavelength conversion member 22.

In this case, a total height of a height of the spacer portion 33 of the optical functional unit 30 and a height of the spacer portion 26 of the wavelength conversion member 22 is preferably formed in a manner in which the thickness T of the low refractive-index portion 40 is in a range of 0.1% or more and 20% or less, especially in a range of 0.1% or more and 10% or less with respect to the length of one side of the top surface of the base portion 31B of the optical functional unit 30.

The height of the spacer portion 33 of the optical functional unit 30 and the height of the spacer portion 26 of the wavelength conversion member 22 may be equally formed, or may be formed in a manner in which the height of one of the spacer portion 26 or the spacer portion 33 is higher.

### (Modification 11)

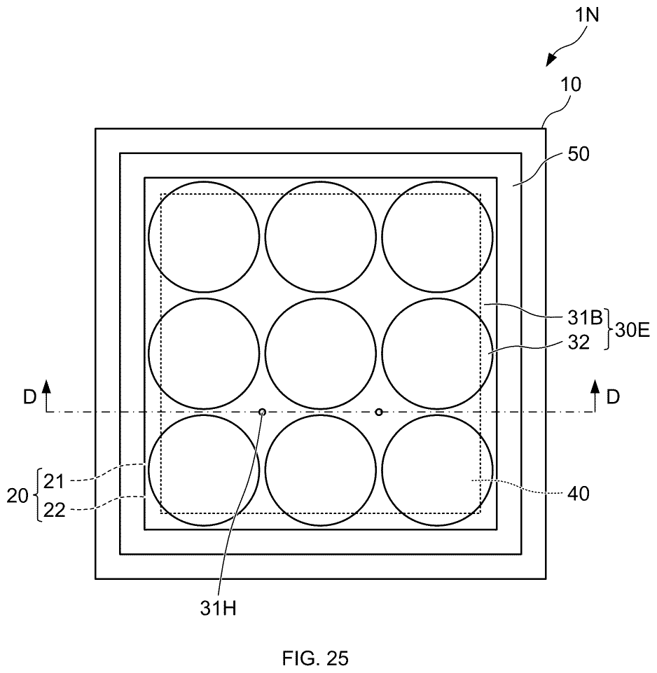

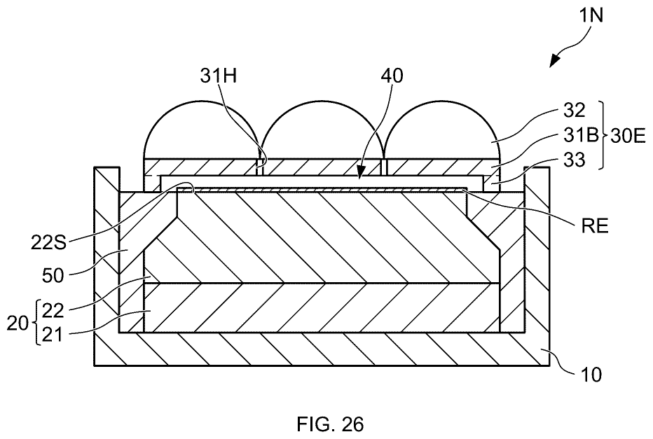

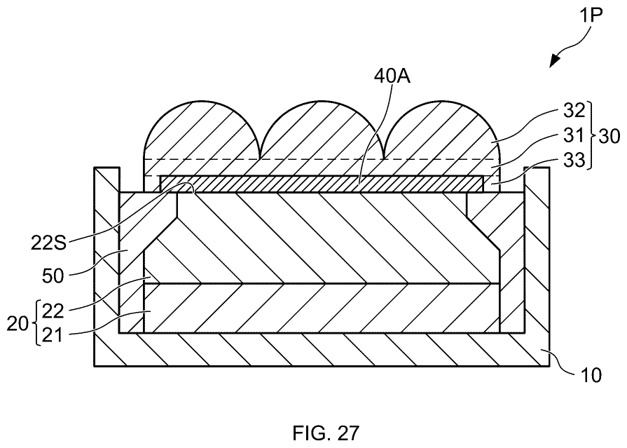

As illustrated in FIG. 25 and FIG. 26, a light-emitting device 1N according to Modification 11 may be provided with through-holes 31H penetrating the base portion 31B of an optical functional unit 30E from a top surface to a lower surface in top view.

FIG. 25 is a top view of the light-emitting device 1N according to Modification 11. FIG. 26 is a cross-sectional view of the light-emitting device 1N taken along a line D-D illustrated in FIG. 25.

As illustrated in FIG. 25, the through-holes 31H are formed in a region in which the projections 32 are not formed in the top surface of the optical functional unit 30E, that is, a region in which the top surface of the base portion 31B is exposed. As illustrated in FIG. 26, the through-holes 31H penetrate the base portion 31B from the top surface to the lower surface. The through-hole 31H is formed, for example, with a diameter of about φ50 μm.

In Embodiment 1 and Modifications 1 to 10, the low refractive-index portion 40 is air, and is a space sealed by the wavelength conversion member 22, the optical functional unit 30E, and the light reflecting member 50.

In this case, the air is expanded by heat generation at the driving of the light-emitting device, the internal pressure inside the low refractive-index portion 40 increases, and a stress thereof possibly causes deterioration in narrow angle performance due to distortion of the optical functional unit 30E or causes dropping off of the optical functional unit 30E.

With the through-holes 31H provided at the base portion 31B of the optical functional unit 30E, even when the air as the low refractive-index portion 40 is expanded by the heat generation at the driving of the light-emitting device 1N, the expanded air is discharged passing through the through-holes 31H. Accordingly, in the light-emitting device 1N, the deterioration in narrow angle performance due to the distortion of the optical functional unit 30E or the dropping off of the optical functional unit 30E can be avoided without the increase of the internal pressure of the low refractive-index portion 40 even at the driving.

### (Modification 12)

As illustrated in FIG. 27, in a light-emitting device 1P according to Modification 12, another material different from air may be filled as a low refractive-index portion 40A.

Embodiment 1 and Modifications 1 to 11 describe the case where the low refractive-index portion 40 is air having the refractive index n=1.0, the optical functional unit 30 is a silicone resin having the refractive index n=1.4, and the refractive index difference between the low refractive-index portion 40 and the optical functional unit 30 is about 0.4.

The low refractive-index portion 40A is, for example, a silicone resin in which porous silica particles or hollow silica particles are dispersed as a filler, and has the refractive index n=about 1.1 to 1.3.

In this case, for the optical functional unit 30, a high refractive index resin material having the refractive index n=about 1.5 to 1.7 or a high refractive index glass material having the refractive index n=about 1.7 to 1.9 can be used.

By selecting appropriate materials to adjust the refractive index difference between the low refractive-index portion 40A and the optical functional unit 30, an angle of refraction on the interface between the low refractive-index portion 40A and the optical functional unit 30 can be adjusted, thereby allowing the adjustment of the narrow angle performance, that is, the directivity of the emitted light emitted from the light-emitting device 1P.

That is, it is only necessary that the refractive index difference between the low refractive-index portion 40A and the optical functional unit 30 is increased in a case of a light-emitting device that requires the larger directivity (proportion of narrow-angle component: large), and the refractive index difference between the low refractive-index portion 40A and the optical functional unit 30 is decreased in a case of a light-emitting device that requires the smaller directivity (proportion of narrow-angle component: small).

By using the resin material for the low refractive-index portion 40A, the thermal expansion by the heat generation at the driving of the light-emitting device 1P can be reduced compared with air, thus allowing suppressing the deterioration in narrow angle performance due to the distortion of the optical functional unit 30 or the dropping off of the optical functional unit 30.

### (Modification 13)

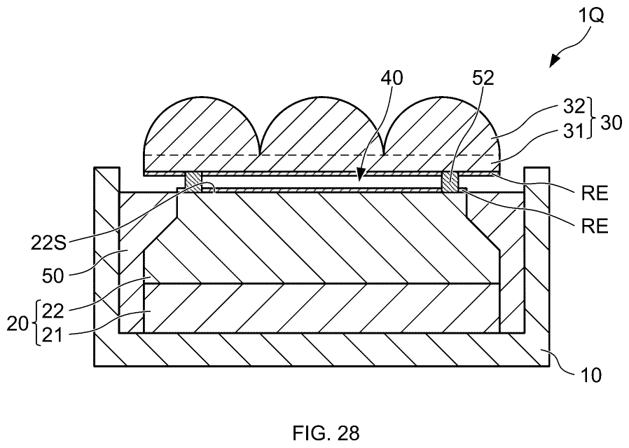

As illustrated in FIG. 28, in a light-emitting device 1Q according to Modification 13, the spacer portion for forming the low refractive-index portion 40 may be formed of another substance.

In the light-emitting device 1Q, a spacer portion 52 that separates the top surface 22S of the wavelength conversion member 22 and the lower surface of the base portion 31 of the optical functional unit 30 by a predetermined distance is provided.

The spacer portion 52 is made of, for example, a thermosetting silicone resin that contains a high content of titanium oxide (TiO₂) particles and has a high viscosity before the effect. The spacer portion 52 is, for example, drawn in a region along an outer periphery of the top surface 22S of the wavelength conversion member 22 by a dispenser. After the spacer portion 52 is heated for a short period to an extent that the viscosity remains on the surface and is put in a provisionally cured state, the optical functional unit 30 is placed from above the spacer portion 52, and then the spacer portion 52 is heated so as to be completely cured. Thus, the spacer portion 52 separates the top surface 22S of the wavelength conversion member 22 and the lower surface of the base portion 31 of the optical functional unit 30 by the predetermined distance, and joins the wavelength conversion member 22 and the optical functional unit 30 to each other.

The light emitted from the region excluding the region in which the spacer portion 52 is formed in the top surface 22S of the wavelength conversion member 22 is, similarly to Embodiment 1, incident on the lower surface of the base portion 31 of the optical functional unit 30 via the low refractive-index portion 40. Accordingly, the light-emitting device 1Q can narrow the angle of the emitted light.

As illustrated in FIG. 28, in the region excluding the region in which the spacer portion 52 is formed in the top surface 22S of the wavelength conversion member 22, and the region excluding the region joined with the spacer portion 52 in the lower surface of the base portion 31 of the optical functional unit 30, the coating layer RE of a fluorine film or the like having a low affinity to the resin material may be formed. This allows suppressing the precursor of silicone resin contained in the spacer portion 52 to spread and wet the top surface 22S of the wavelength conversion member 22 and the lower surface of the base portion 31 of the optical functional unit 30.

The spacer portion 52 may be drawn to be formed in the region along the outer periphery of the top surface 22S of the wavelength conversion member 22, or may be formed intermittently or in dots at positions in symmetry with respect to the center point of the top surface 22S of the wavelength conversion member 22.

The spacer portion 52 may contain spherical particles as a spacer that separates the top surface 22S of the wavelength conversion member 22 and the lower surface of the base portion 31 of the optical functional unit 30 by the predetermined distance.

### (Modification 14)

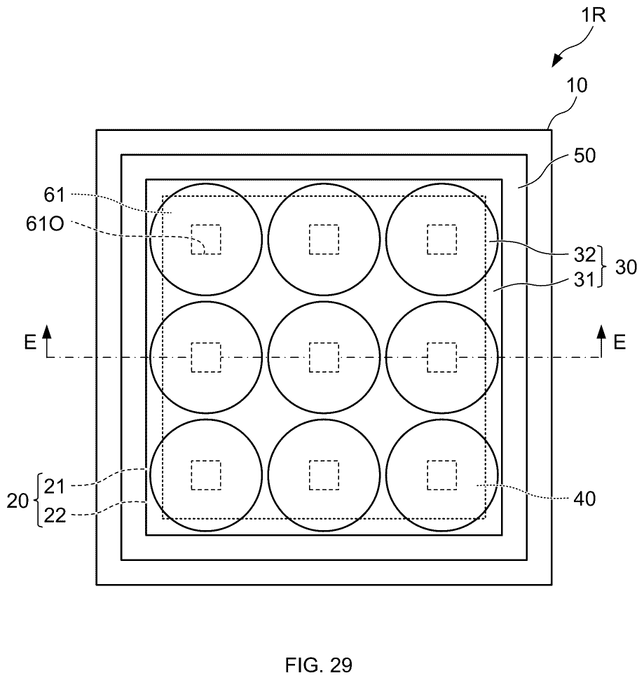

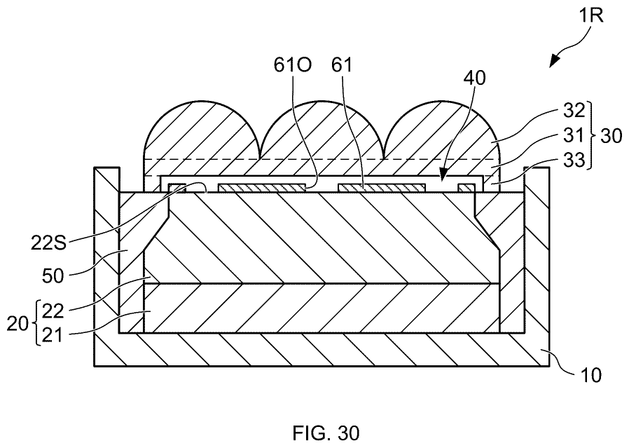

As illustrated in FIG. 29 and FIG. 30, a light-emitting device 1R according to Modification 14 may include a light shielding film 61 that blocks a light on a part of the top surface 22S of the wavelength conversion member 22.

FIG. 29 is a top view of the light-emitting device 1R according to Modification 14. FIG. 30 is a cross-sectional view of the light-emitting device 1R taken along a line E-E illustrated in FIG. 29.

The light shielding film 61 is, for example, a reflective film formed of a multilayer reflecting film or a metal film that reflects the light traveling upward from the inside of the wavelength conversion member 22.

The light shielding film 61 is provided with an opening portion 610 that opens a region immediately below the center point of the projection 32 in top view. That is, the light is emitted from only the opening portion 610 part of the light shielding film 61 in the top surface 22S of the wavelength conversion member 22.

This allows suppressing the light incident from the lower surface of the base portion 31 of the optical functional unit 30 in the region immediately below one projection 32 to be incident on another adjacent projection 32 in the base portion 31. Accordingly, the light-emitting device 1R can emit the light of only the component in narrower-angle, thus allowing increasing the proportion of the narrow-angle component in the emitted light from the light-emitting device 1R.

The light traveling upward inside the wavelength conversion member 22 and reflected downward by the light shielding film 61 is highly possibly reflected upward again by the reflective film formed at the lower surface side of the semiconductor light-emitting element 21 and emitted from the opening portion 610 of the light shielding film 61. Accordingly, by forming the light shielding film 61 provided with the opening portion 610 on the top surface 22S of the wavelength conversion member 22, the amount of luminous flux of the light emitted from the opening portion 610 can be increased, and the amount of luminous flux of the narrow-angle component in the light emitted from the light-emitting device 1R can be increased.

### (Modification 15)

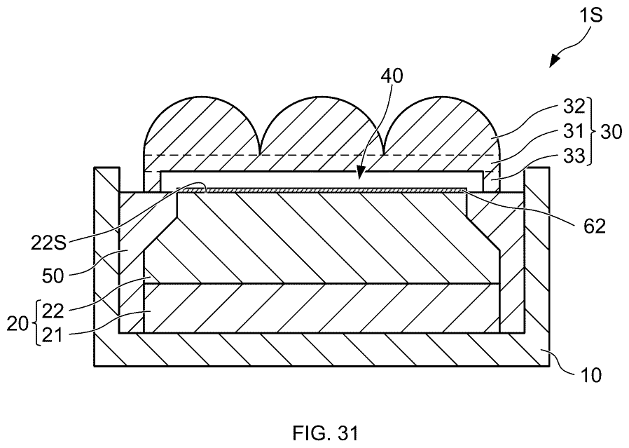

As illustrated in FIG. 31, a light-emitting device 1S according to Modification 15 may include an optical multilayer film 62 formed on the top surface 22S of the wavelength conversion member 22.

The optical multilayer film 62 controls the transmittance of each wavelength in the light emitted from the top surface 22S of the wavelength conversion member 22 to suppress the chromaticity change due to the change of the emission angle, thereby improving the uniformity of chromaticity. The optical multilayer film 62 can be formed by laminating a plurality of optical layers different in refractive index. For example, for the material of the low refractive index layer, a transparent dielectric material having the refractive index of, for example, in a range of 1.6 or less, such as SiO₂, MgF₂, is used, and for the material of the high refractive index layer, TiO₂, Al₂O₃, ZrO₂, HfO₂, Nb₂O₅, BaTi₂O₅, Ta₂O 5, and the like having the refractive index of 1.6 or more are used.

### (Modification 16)

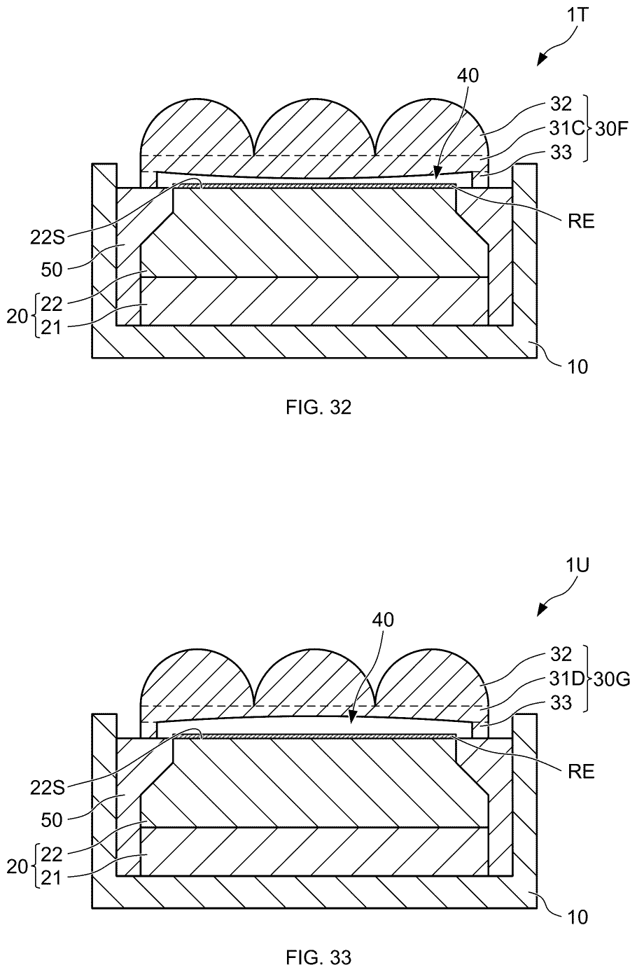

As illustrated in FIG. 32, in a light-emitting device 1T according to Modification 16, a lower surface of a base portion 31C of an optical functional unit 30F may be formed in a shape protruding downward.

By forming the lower surface of the base portion 31C of the optical functional unit 30F in the shape protruding downward, the light emitted from the top surface 22S of the wavelength conversion member 22 is collected inward according to Snell's law due to the lens effect of the lower surface of the base portion 31C. Accordingly, the luminance in the vicinity of the center of the light-emitting surface of the light-emitting device 1T can be increased.

### (Modification 17)

As illustrated in FIG. 33, in a light-emitting device 1U according to Modification 17, a lower surface of a base portion 31D of an optical functional unit 30G may be formed in a shape protruding upward. This allows reducing a luminance difference inside the light-emitting surface when observed from immediately above the light-emitting device 1U.

### (Modification 18)

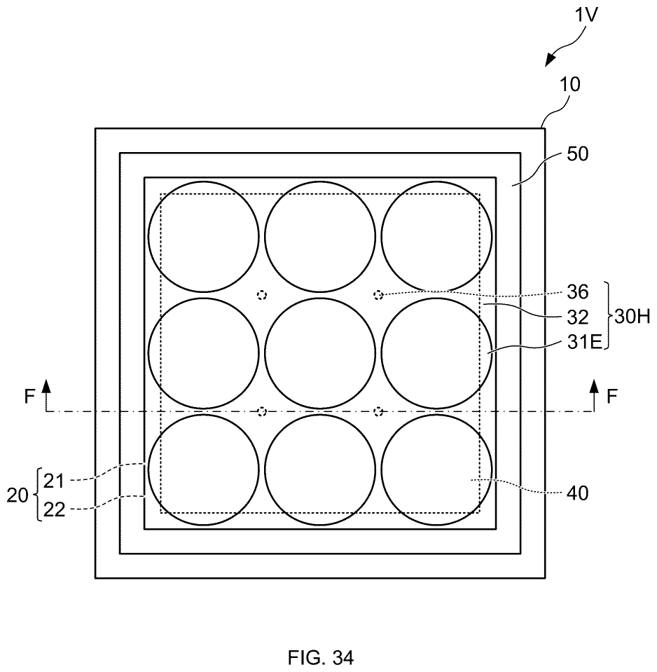

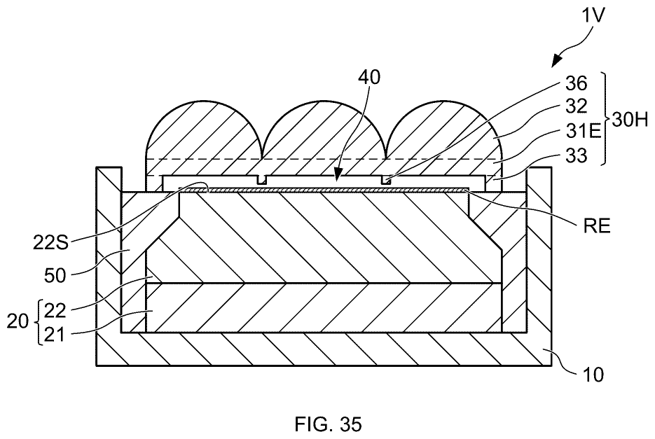

As illustrated in FIG. 34 and FIG. 35, a light-emitting device 1V according to Modification 18 may be provided with protruding portions 36 formed in a shape protruding downward on a lower surface of a base portion 31E of an optical functional unit 30H.

FIG. 34 is a top view of the light-emitting device 1V according to Modification 18. FIG. 35 is a cross-sectional view of the light-emitting device 1V taken along a line F-F illustrated in FIG. 34.

The protruding portion 36 is a protruding portion integrally formed with the base portion 31E. For example, as illustrated in FIG. 34, the protruding portions 36 are formed in a region in which the projections 32 are not formed in the top surface of the optical functional unit 30, that is, on the lower surface of the base portion 31E immediately below the region in which the top surface of the base portion 31E is exposed, in top view.

A height of the protruding portion 36 is formed to be a height, for example, smaller than the thickness of the low refractive-index portion 40 and not in contact with the coating layer RE.

By forming the protruding portions 36 on the lower surface of the base portion 31E of the optical functional unit 30H, the protruding portions 36 function as a stopper that ensures the thickness of the low refractive-index portion 40 when the base portion 31E of the optical functional unit 30H is distorted in the shape protruding downward due to the heat generation at the driving of the light-emitting device 1V.

Accordingly, the light-emitting device 1V can ensure the thickness of the low refractive-index portion 40 even at the driving, and can suppress the deterioration in narrow angle performance on the emitted light.

The protruding portion 36 may be formed in a pillar shape, a conical shape, or a frustum shape from the lower surface of the base portion 31E.

### (Modification 19)

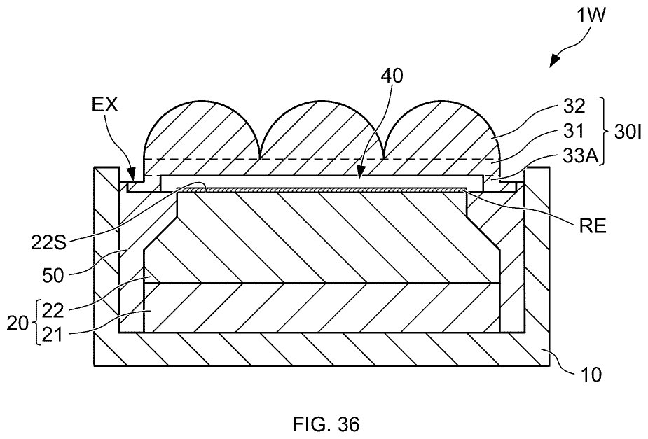

As illustrated in FIG. 36, a light-emitting device 1W according to Modification 19 may be provided with an expanded portion EX extending outward from an outer surface of a spacer portion 33A in a lower end region of the outer surface of the spacer portion 33A of an optical functional unit 30I.

As illustrated in FIG. 36, forming the expanded portion EX increases an area of the lower surface of the spacer portion 33A, thus allowing increasing the bonding area with the light reflecting member 50. This allows enhancing the bonding strength of the optical functional unit 30I.

By forming the light reflecting member 50 up to the outer surface of the expanded portion EX, the bonding strength of the optical functional unit 30 can be further enhanced.

Since the bonding area of the lower surface of the spacer portion 33A of the optical functional unit 30 can be increased, the light reflecting member 50 does not need to be formed up to the outer surface of the expanded portion EX. Meanwhile, similarly to the description of Embodiment 1, the light reflecting member 50 may be formed to extend up to the top surface of the expanded portion EX, and may be formed to cover up to the region at the lower end of the outer surface of the base portion 31.

The lower surface of the spacer portion 33A may be provided on the top surface 22S of the wavelength conversion member 22 or the top surface 21S of the semiconductor light-emitting element 21, and the expanded portion EX may be protruded outward from the top surface 22S of the wavelength conversion member 22 or the top surface of the semiconductor light-emitting element 21 to be joined with the light reflecting member 50.

### (Modification 20)

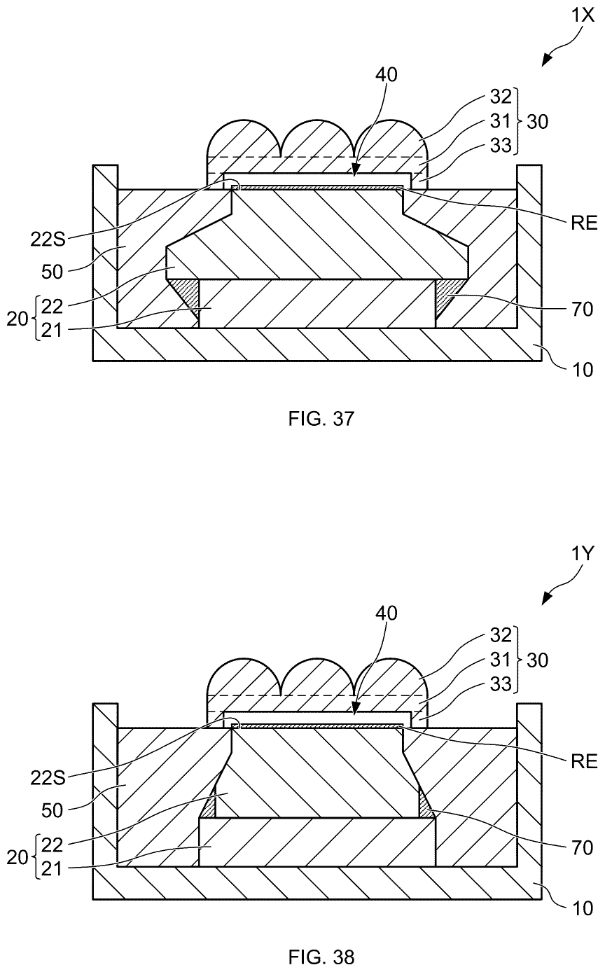

As illustrated in FIG. 37, in a light-emitting device 1X according to Modification 20, the top surface of the semiconductor light-emitting element 21 and the lower surface of the wavelength conversion member 22 may be different in size.

When the lower surface of the wavelength conversion member 22 is larger than the top surface of the semiconductor light-emitting element 21 in size, the light guide portion 70 that extends from the side surface of the semiconductor light-emitting element 21 to an outer edge portion of the lower surface of the wavelength conversion member 22 and is made of a light-transmitting resin may be formed.

By forming the light guide portion 70, the light emitted from the side surface of the semiconductor light-emitting element 21 and incident on the light guide portion 70 can be reflected by the light reflecting member 50 and guided to the lower surface of the wavelength conversion member 22 in the upper direction.

Accordingly, the light extraction efficiency of the light-emitting device 1X can be improved.

### (Modification 21)

As illustrated in FIG. 38, in a light-emitting device 1Y according to Modification 21, when the lower surface of the wavelength conversion member 22 is smaller than the top surface of the semiconductor light-emitting element 21 in size, the light guide portion 70 that extends from the outer edge of the top surface of the semiconductor light-emitting element 21 to the lower end of the inclined surface of the side surface of the wavelength conversion member 22 and is made of a light-transmitting resin may be formed.

By forming the light guide portion 70, the light emitted from the side surface of the wavelength conversion member 22 and incident on the light guide portion 70 can be reflected by the light reflecting member 50 and incident again from the side surface of the wavelength conversion member 22.

Accordingly, the light extraction efficiency of the light-emitting device 1Y can be improved.

### (Modification 22)

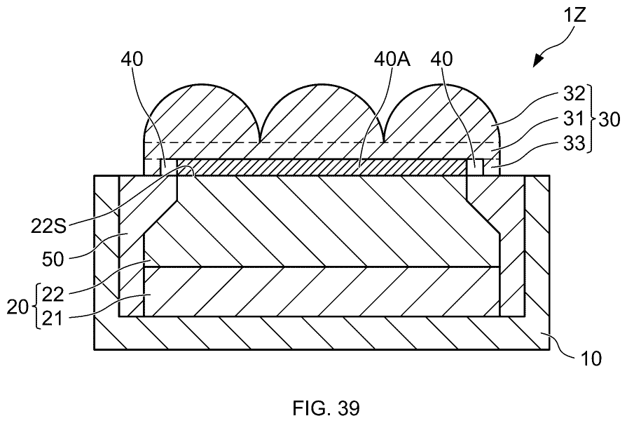

As illustrated in FIG. 39, in a light-emitting device 1Z according to Modification 22, similarly to the light-emitting device 1P according to Modification 12 described above, when a substance different from air is used as the low refractive-index portion 40A, the low refractive-index portion 40A can be formed on the top surface 22S of the wavelength conversion member 22.

For the low refractive-index portion 40A, for example, a transparent resin that is formed of a silicone resin in which porous silica particles or hollow silica particles are dispersed as a filler and has the refractive index n=about 1.05 to 1.3 can be used.

In this case, for the optical functional unit 30, a high refractive index resin material having the refractive index n=about 1.4 to 1.7 or a high refractive index glass material having the refractive index n=about 1.7 to 1.9 can be used.

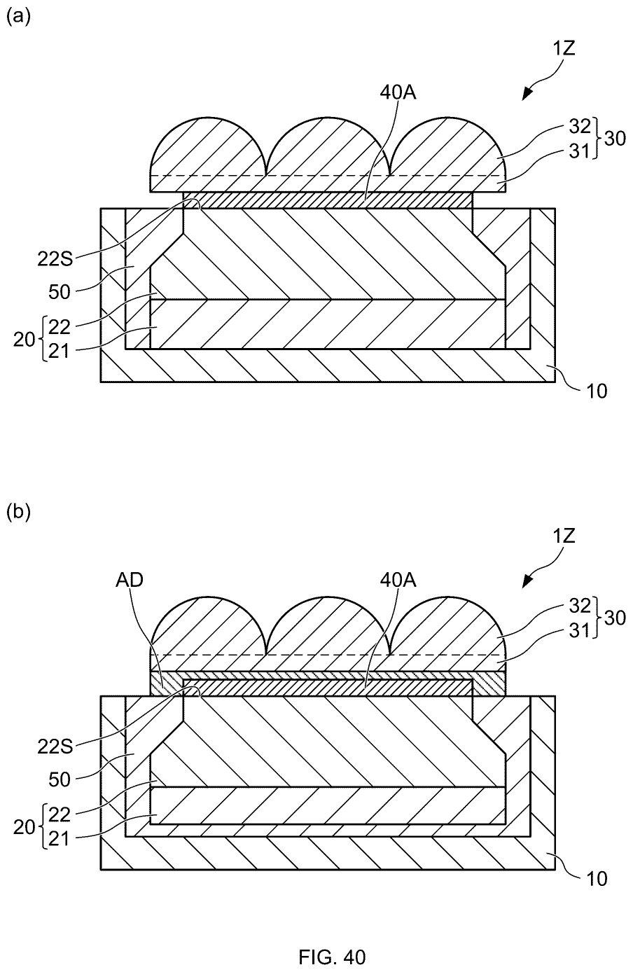

As illustrated in FIG. 40(a), the optical functional unit 30 in the light-emitting device 1Z may have a configuration without the spacer portion 33.

The low refractive-index portion 40A and the optical functional unit 30 can be joined to each other by an appropriate joining method.

For example, as illustrated in FIG. 40(a), bonding using a transparent adhesive sheet (not illustrated), direct joining, or the like may be performed.

The low refractive-index portion 40A may be preliminarily formed on the bottom surface of the optical functional unit 30 and joined on the top surface 22S of the wavelength conversion member 22 by an appropriate method. In this case, the low refractive-index portion 40A can be formed on the entire bottom surface of the optical functional unit 30 and formed to have a width approximately same as that of the optical functional unit 30. The low refractive-index portion 40A may be formed at the position opposed to the top surface 22S on the bottom surface of the optical functional unit 30 corresponding to the width of the top surface 22S of the wavelength conversion member 22.

For example, as illustrated in FIG. 40(b), the optical functional unit 30 can be bonded on the low refractive-index portion 40A by applying a liquid adhesive AD. When the adhesive AD is applied, the adhesive AD may be applied over the top surface of the light reflecting member 50.

### (Verification of the Number of Projections to Be Arranged and Thickness of Low Refractive-Index Portion)

In Embodiment 1 described above, as described in FIG. 6, the case where the nine projections 32 of the optical functional unit 30 in total are arranged in a matrix of three rows and three columns is described.

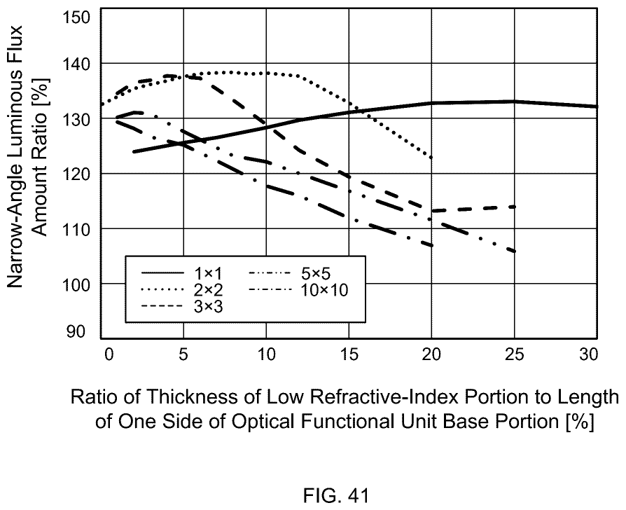

FIG. 41 is a drawing illustrating a simulation result of the thickness T2 of the low refractive-index portion 40 and the luminous flux amount ratio of the narrow-angle component of the light emitted from the light-emitting device 1 when the projections 32 of the optical functional unit 30 are arranged in one row and one column, two rows and two columns, three rows and three columns, five rows and five columns, and ten rows and ten columns.

In FIG. 41, similarly to the arrangement of the projections 32 described in FIG. 9, the projections 32 are provided in respective compartments into which the top surface of the base portion 31 of the optical functional unit 30 is equally divided in the X and Y directions from one row and one column (one compartment in total) to ten rows and ten columns (100 compartments in total). Each of the projections 32 is formed in a hemispherical shape with the radius R1 having the center point P1 of each compartment as the center.

Similarly to Embodiment 1 described above, the simulation was performed with the light-emitting portion 20 in which the light-emitting surface of the semiconductor light-emitting element 21 is a square having the length D1 of one side of 1.0 mm and the top surface 22S of the wavelength conversion member 22 has the square top surface having the length D2 of one side of 0.85 mm.

The simulation was performed assuming that the thickness T1 of the base portion 31 of the optical functional unit 30 is the thickness of 5% of the length of one side of the top surface of the base portion 31, that is, the thickness T1 of the base portion 31 is 50 μm.

The horizontal axis of FIG. 41 indicates a ratio of the thickness T2 of the low refractive-index portion 40 to a length D3 of one side of the top surface of the base portion 31 of the optical functional unit 30. the ratio 0% of the thickness T2 of the low refractive-index portion 40 on the horizontal axis of FIG. 41 means a state where the low refractive-index portion 40 is not provided in the light-emitting device 1, that is, a state where the spacer portion 33 is not disposed and the lower surface of the base portion 31 is in contact with the top surface 22S of the wavelength conversion member 22.

The vertical axis of FIG. 41 indicates the luminous flux amount ratio in a narrow angle range (±30°) when the ratio of the thickness T2 of the low refractive-index portion 40 is changed. On the vertical axis of FIG. 41, the amount of luminous flux in a narrow angle range of a light-emitting device that is not provided with the optical functional unit 30 and emits a light having a directivity of the ideal Lambertian orientation from the top surface of the wavelength conversion member is assumed to be 100%. In the light-emitting device that emits the light having the directivity of the ideal Lambertian orientation, the top surface shape of the wavelength conversion member is set to a square having one side of 1.0 mm.

In FIG. 41, the solid line indicates the simulation result when the projections 32 are arranged in one row and one column, the one-dot chain line indicates that in two rows and two columns, the dashed line indicates that in three rows and three columns, the two-dot chain line indicates that in five rows and five columns, and the dotted line indicates that in ten rows and ten columns.

As illustrated in FIG. 41, by disposing the low refractive-index portion 40 between the top surface 22S of the wavelength conversion member 22 and the lower surface of the base portion 31, the amount of luminous flux in the narrow angle range increases.

It was found that the satisfactory amount of luminous flux is obtained in the cases where the number of the projections 32 to be arranged is two rows and two columns, and three rows and three columns.

Specifically, in the case where the number of the projections 32 to be arranged is three rows and three columns similar to that of the light-emitting device of Embodiment 1, the narrow-angle luminous flux amount ratio became 130% or more when the ratio of the thickness T2 of the low refractive-index portion 40 to the length of one side of the top surface of the base portion 31 of the optical functional unit 30 is in a range of 0.6% or more and 9.4% or less (see FIG. 6 and FIG. 41).

In the case where the number of the projections 32 to be arranged became two rows and two columns, the narrow-angle luminous flux amount ratio is 130% or more when the ratio of the thickness T2 of the low refractive-index portion 40 to the length of one side of the top surface of the base portion 31 of the optical functional unit 30 is in a range of 0.1% or more and 17.0% or less.

From the simulation result of FIG. 41, it was found that in the case where the number of the projections 32 to be arranged is varied, when the arrangement number is four of two rows and two columns, an allowable range of the thickness T2 of the low refractive-index portion 40 to the narrow-angle component of the light emitted from the light-emitting device 1 is largest.

### Embodiment 2

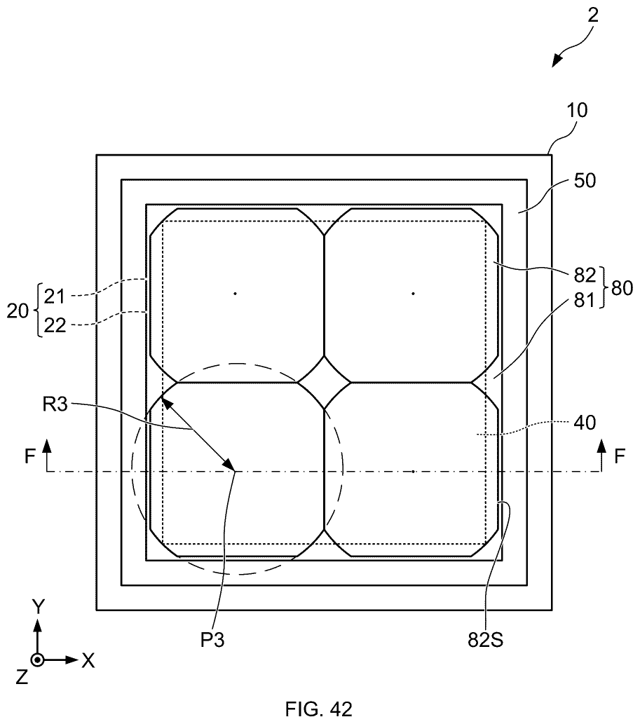

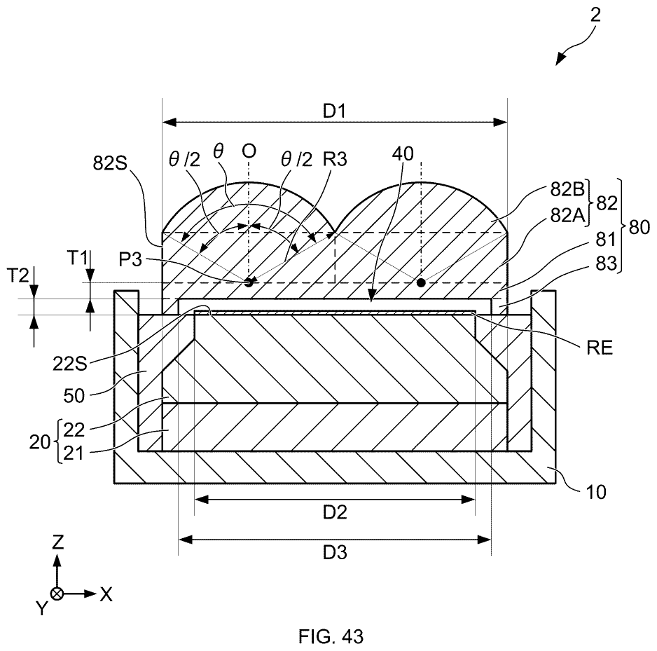

FIG. 42 is a top view of a light-emitting device 2 according to Embodiment 2. FIG. 43 is a cross-sectional view of the light-emitting device 2 taken along a line F-F illustrated in FIG. 42. In FIG. 43, D1 indicates the length of one side of the top surface shape of the semiconductor light-emitting element 21. D1 approximately matches one side of an outer shape of a base portion 81 of an optical functional unit 80. D2 indicates a length of one side of a top surface of a wavelength conversion unit. D3 indicates a length of one side of a surface opposed to the top surface 22S of the wavelength conversion unit in an incident surface of the optical functional unit 80.

In Embodiment 2, since the substrate 10, the light-emitting portion 20, and the light reflecting member 50 are configured similarly to Embodiment 1, the description is omitted.

Embodiment 2 is different from Embodiment 1 in that each of projections 82 formed on the base portion 81 of the optical functional unit 80 has a flat side surface 82S extending in a direction along a side surface of the base portion 81, that is, a direction perpendicular to the top surface of the base portion 81 in each region along an outer edge of the base portion 81.

Further, Embodiment 2 is different from Embodiment 1 in that the number of the projections 82 of the optical functional unit 80 to be arranged is configured to be two rows and two columns based on the simulation result indicated in FIG. 41.

Each of the projections 82 is formed in a hemispherical shape having a radius of a radius R3 from a center point P3 of each compartment when the top surface of the base portion 81 is equally divided into compartments of two rows and two columns in the X and Y directions.

The projection 82 is formed to have a dimension of the radius R3 exceeding a length of a half of one side of the compartment. That is, in top view, each of the projections 82 has a boundary with the adjacent projection 82 at a straight line portion, and is formed in an arc shape at the other portion. In other words, in top view, the projection 82 has a shape in which arcs and straight lines are combined.

At the region along the outer edge of the base portion 81 of the projection 82, the flat side surface 82S is formed in the direction along the side surface of the base portion 81.

In other words, the projection 82 has a shape obtained by cutting a hemisphere having the radius R3 at facing surfaces of overlapping portions of the mutually adjacent projections 82 and the flat side surfaces 82S.

As illustrated in FIG. 43, the projection 82 includes a first part 82A having a rectangular cross-sectional surface shape in a cross section passing through the respective center points P3 of the mutually adjacent projections 82, and a spherical cap-shaped second part 82B that has an arched cross-sectional surface shape in the cross section passing through the center points P3 and is provided on each first part 82A and continuously formed with each first part 82A.

An upper end of the flat side surface 82S and an upper end of a contact plane with the mutually adjacent projection 82 are formed to have the same height from the base portion 81. That is, the first part 82A has a rectangular cross-sectional surface shape in a cross section (cross section along the line F-F in FIG. 42) passing through the center points P3 of the respective compartments on the top surface of the base portion 81. Respective distances from the center point P3 to the upper end of the flat side surface 82S and the upper end of the contact plane with the mutually adjacent projection 82 are same as the radius R3.

The second part 82B is continuously formed with the first part 82A from the end portion of the top surface of the first part 82A in a spherical cap shape having the radius R3.

In the cross section passing through the center points P3, an angle between a straight line connecting from the upper end of the flat side surface 82S to the center point P3 and a straight line connecting from the center point P3 to the upper end of the contact plane with the mutually adjacent projection 82 is defined as an angle θ. Lines connecting from the center point P3 of the second part 82B to respective both ends of the end portion of the top surface of the first part 82A have the same angle with respect to a center line O that is a line perpendicular to the top surface of the base portion 81 passing through the center point P3, that is, each angle is θ/2.

The angle θ of the second part 82B is an opening angle of the second part 82B as a lens when the center point P3 is assumed to be a point light source.

In other words, in the cross section passing through the respective center points P3 of the mutually adjacent projections 82, the surface of the second part 82B has a spherical cap-shaped curved surface, and its polar angle is θ/2.

The angle θ and the height of the first part 82A from the top surface of the base portion 81 are determined based on the radius R3 of the projection 82.

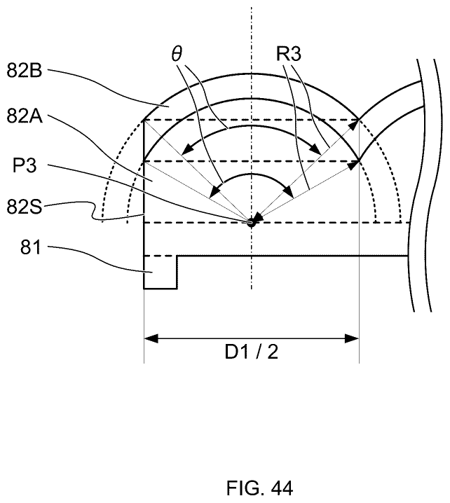

FIG. 44 is a drawing schematically illustrating a case where the angle θ is varied for the projection 82 in Embodiment 2. FIG. 44 illustrates one projection 82, and the length of one projection in the cross section passing through the center point P3 (cross section along the line F-F in FIG. 42) is D1/2.

As illustrated in FIG. 44, when the radius R3 of the projection 82 is small, the height of the first part 82A from the top surface of the base portion 81 decreases, and the angle θ increases. In contrast, when he radius R3 of the projection 82 is large, the height of the first part 82A from the top surface of the base portion 81 increases, and the angle θ decreases.

### (Verification of Opening Angle of Second Part)

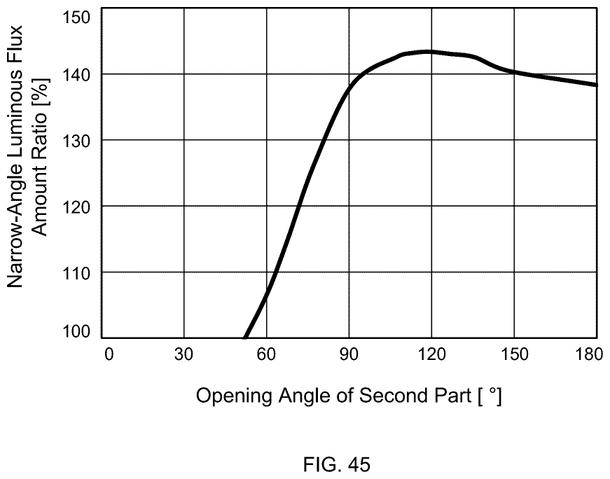

FIG. 45 is a drawing illustrating a simulation result of the luminous flux amount ratio of the narrow-angle component of the light emitted from the light-emitting device 2 when the angle θ as the opening angle of the second part 82B of the projection 82 of the optical functional unit 80 is changed.

In FIG. 45, the simulation was performed with the light-emitting portion 20 in which, similarly to Embodiment 1, the semiconductor light-emitting element 21 has the square light-emitting surface with the length D1 of one side of 1.0 mm and the top surface 22S of the wavelength conversion member 22 has the square top surface with the length D2 of one side of 0.85 mm.

The simulation was performed, similarly to Embodiment 1, with the optical functional unit 80 in which the base portion 81 has the square outer shape having one side of 1.0 mm. The thickness T1 of the base portion 81 of the optical functional unit 80 and the height T2 of a spacer portion 83 of the optical functional unit 80 are each set to the thickness of 5% of the length of one side of the top surface of the base portion 81. That is, the simulation was performed with the thickness T1 of the base portion 81 of the optical functional unit 80 and the thickness T2 of the spacer portion 83 of the optical functional unit 80 each set to 50 μm.

The horizontal axis of FIG. 45 indicates the angle θ as the opening angle of the second part 82B of the optical functional unit 80. In this simulation, the simulation was performed by varying the angle θ from 50° to 180°.

As described above, as the angle θ increases, the radius R3 of the projection 82 decreases.

When the angle θ of the horizontal axis of FIG. 45 becomes 180°, the projection 82 is formed of only the hemispherical projection.

The vertical axis of FIG. 45 indicates the luminous flux amount ratio in a narrow angle range (+30°) when the angle θ of the second part 82B is changed. On the vertical axis of FIG. 45, the amount of luminous flux in a narrow angle in a light-emitting device in which the optical functional unit 80 is not disposed and a light having a directivity of the ideal Lambertian orientation is emitted from the top surface of the wavelength conversion member is assumed to be 100%. In the light-emitting device that emits the light having the directivity of the ideal Lambertian orientation, the top surface shape of the wavelength conversion member is set to a square having one side of 1.0 mm.

As illustrated in FIG. 45, when the angle θ of the second part 82B of the optical functional unit 80 is in a range of 52° or more and 100° or less, the narrow-angle luminous flux ratio exceeded 100%. When the angle θ of the second part 82B of the optical functional unit 80 is in a range of 80° or more and 180° or less, the narrow-angle luminous flux amount ratio was 130% or more. Furthermore, it was found that when the angle θ of the second part 82B of the optical functional unit 80 is in a range of 95° or more and 150° or less, the narrow-angle luminous flux amount ratio becomes highest. It was found that the angle θ at which the narrow-angle luminous flux amount ratio has the peak is 119°.

As described above, and as illustrated in FIG. 43, FIG. 44, the surfaces of the second parts 82B of the mutually adjacent projections 82 have the spherical cap-shaped curved surfaces. In the cross section passing through the center point P3 (cross section along the line F-F in FIG. 42), the angle between the line from the center P3 of the sphere to the apex of the spherical cap and the end portion of the spherical cap curved surface (point in contact with the end portion of the top surface of the first part 82A), that is, the polar angle is θ/2.

That is, when the surface of the second part 82B has the polar angle (θ/2) in the spherical cap-shaped curved surface of 26° or more and 90° or less, the high narrow-angle luminous flux amount was able to be obtained. When the polar angle is 40° or more and 90° or less, the further higher narrow-angle luminous flux amount can be obtained, and when the polar angle is 47.5° or more and 75° or less, the further higher luminous flux amount can be obtained.

### (Verification of Base Portion Thickness of Optical Functional Unit)

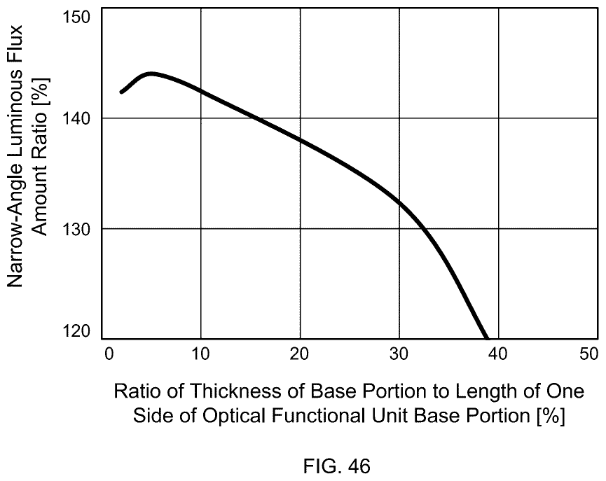

FIG. 46 is a drawing illustrating a simulation result of the luminous flux amount ratio of the narrow-angle component of the light emitted from the light-emitting device 2 when the thickness T1 of the base portion 81 of the optical functional unit 80 is changed.

In FIG. 46, the simulation was performed with the angle θ of the second part 82B of the optical functional unit 80 set to 119° based on the simulation result illustrated in FIG. 45. The other structure of the light-emitting device 2 is similar to the structure described in FIG. 45.

The lower horizontal axis of FIG. 46 indicates a ratio of the thickness T1 of the base portion 81 to the length of one side of the top surface of the base portion 81 of the optical functional unit 80.

In FIG. 46, the simulation was performed by varying the ratio of the thickness T1 of the base portion 81 to the length of one side of the top surface of the base portion 81 of the optical functional unit 80 from 2% to 40%.

The simulation was performed with the ratio of the thickness of the spacer portion 83 of the optical functional unit 80, that is, the thickness of the thickness T2 of the low refractive-index portion 40 set to 5%.

The vertical axis of FIG. 46 indicates the luminous flux amount ratio in a narrow angle range (±30° ) when the ratio of the thickness T1 of the base portion 81 is changed. On the vertical axis of FIG. 46, similarly to FIG. 45, the amount of luminous flux in a narrow angle in a light-emitting device in which the optical functional unit 80 is not disposed and a light having a directivity of the ideal Lambertian orientation is emitted from the top surface of the wavelength conversion member is assumed to be 100%. In the light-emitting device that emits the light having the directivity of the ideal Lambertian orientation, the top surface shape of the wavelength conversion member is set to a square having one side of 1.0 mm.

As illustrated in FIG. 46, in the range of 2% or more and 33% or less of the ratio of the thickness T1 of the base portion 81 of the optical functional unit 80, which is the simulation range, the narrow-angle luminous flux amount ratio was 130% or more.

When the thickness T1 of the base portion 81 of the optical functional unit 80 is in a range of 2% or more and 15% or less, the narrow-angle luminous flux amount ratio was 140% or more. It was found that within the range, when the thickness T1 of the base portion 81 of the optical functional unit 80 is set to a range of 2% or more and 10% or less, a large effect is provided on the narrow-angle luminous flux amount ratio.

It was found that in the range on which the simulation was performed, when the ratio of the thickness T1 of the base portion 81 is 5%, it is most effective for the narrow-angle luminous flux amount ratio.

### (Action of Projection of Optical Functional Unit in Embodiment 2)

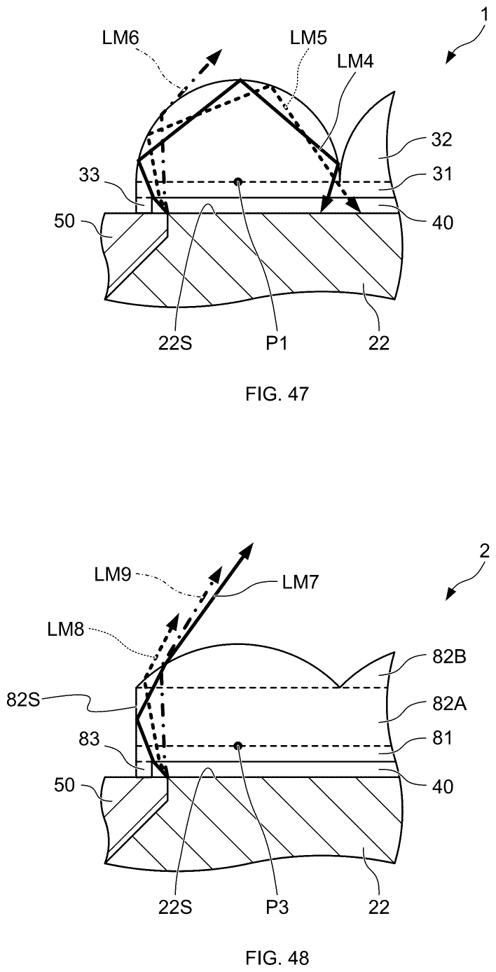

With reference to FIG. 47 and FIG. 48, the action of the projection 82 of the light-emitting device 2 in Embodiment 2 is described.

FIG. 47 and FIG. 48 are enlarged cross-sectional views of the wavelength conversion member 22 and the optical functional units 30, 80 in the cross-sectional surfaces of FIG. 2 and FIG. 43. To facilitate the description of optical paths of emitted lights LM4, LM5, LM6, LM7, LM8, LM9 from the light-emitting devices 1, 2, the coating layer RE is not illustrated, and hatching of the optical functional units 30, 80 is omitted.

FIG. 47 is a drawing illustrating the optical paths of the emitted lights LM4, LM5, LM6 as a part of the light emitted from the end portion of the top surface 22S in the emitted light emitted from the top surface 22S of the wavelength conversion member 22 in the light-emitting device 1 of Embodiment 1.

FIG. 48 is a drawing illustrating the optical paths of the emitted lights LM7, LM8, LM9 as a part of the light emitted from the end portion of the top surface 22S in the emitted light emitted from the top surface 22S of the wavelength conversion member 22 in the light-emitting device 2 of Embodiment 2.

FIG. 47 and FIG. 48 describe a case where the emitted lights LM4, LM5, LM6 and the emitted lights LM7, LM8, LM9 are emitted outward from the end portion of the top surface 22S with the same angles, respectively. That is, in FIG. 47 and FIG. 48, the emitted light LM4 and the emitted light LM7 indicated by the solid line, the emitted light LM5 and the emitted light LM8 indicated by the dashed line, and the emitted light LM6 and the emitted light LM9 indicated by the one-dot chain line are emitted from the end portion of the top surface 22S with the respective same angles.

The description is given of the case where the emission angles of the emitted lights LM4, LM5, LM6 and the emitted lights LM7, LM8, LM9 become close to the optical axis direction (axial direction of the lens) in the respective orders of the emitted lights LM4, LM5, LM6 and the emitted lights LM7, LM8, LM9.

In FIG. 47, the projection 32 is a hemispherical lens. Therefore, especially, in the outer end region of the projection 32 in top view, the incident angle on the surface (contact plane) of the projection 32 of the light, such as emitted lights LM4, LM5, having the large inclination angle from the optical axis direction, that is, an angle to a contact line at a point incident on the surface of the projection 32 tends to increase.

This causes the emitted lights LM4, LM5 to be repeatedly totally reflected on the surface of the projection 32 and become return lights to the wavelength conversion member 22, and a part of them possibly becomes a light not emitted from the projection 32 or a light not emitted within the narrow angle range.

Therefore, among the emitted lights LM4, LM5, LM6 emitted outward from the end portion of the top surface 22S illustrated in FIG. 47, only the emitted light LM6 having the emission angle relatively close to the optical axis direction is emitted from the surface of the projection 32 to air as the outside.

In contrast, as illustrated in FIG. 48, in the light-emitting device 2 according to Embodiment 2, the emitted light can be more efficiently extracted from the optical functional unit 80 with the surface of the flat side surface 82S and the second part 82B than in Embodiment 1.

Specifically, the light, such as the emitted light LM7 having the largest inclination angle from the optical axis direction, is totally reflected on the surface of the flat side surface 82S that is the side surface of the first part 82A, and emitted from the surface of the second part 82B to the air as the outside.

In the second part 82B, the radius R3 of the projection 82 is larger than the radius R1 of the projection 32 of Embodiment 1, that is, the curvature of the surface of the second part 82B is larger than that of the projection 32 of Embodiment 1. Therefore, the light, such as the emitted light LM8 having the largest inclination angle from the optical axis direction next to the emitted light LM7, can be decreased in incident angle on the surface (contact plane) of the second part 82B, and the total reflection of the emitted light LM8 can be suppressed.

Therefore, the emitted light LM8 is refracted in the narrow angle direction on the surface of the second part 82B, and emitted from the second part 82B to air as the outside.

Thus, in the light-emitting device 2 according to Embodiment 2, the light can be more efficiently extracted from the optical functional unit 80.

Accordingly, the light-emitting device 2 according to Embodiment 2 can increase the luminous flux amount of the light emitted from the light-emitting device 2.

The inventors verified that the light-emitting device 2 of Embodiment 2 improves the luminous flux amount of the narrow-angle component by about 3.5% compared with the light-emitting device 1 of Embodiment 1.

While the case where the four projections 82 in total of two rows and two columns are arranged is described in the light-emitting device 2 according to Embodiment 2, the nine projections 82 in total of three rows and three columns may be arranged based on the simulation result of FIG. 41.

In the light-emitting device 2 according to Embodiment 2, as illustrated in FIG. 42, the case of the shape in which the angle θ as the opening angle of the second part 82B of the projection 82 is within the range described in FIG. 45 in the cross section passing through the respective center points P3 of the mutually adjacent projections 82 is described. However, the shape of the projection 82 is not limited to this.

For example, in top view, in the cross section passing through the respective center points P3 of the projections 82 arranged at diagonal positions of the top surface of the base portion 81, the projections 82 may be formed to have a shape in which the projections 82 arranged at diagonal positions of the top surface of the base portion 81 overlap with each other and each have the flat side surface 82S as illustrated in FIG. 43.

That is, it is only necessary that the angle θ as the opening angle of the second part 82B is within the range described in FIG. 45 in a cross section passing through the respective center points P3 of a plurality of the projections 82.

In the description of the light-emitting devices according to Embodiment 1 and Embodiment 2, for example, the coating layer RE configured of a fluororesin having a property of repelling an uncured resin is formed. However, the coating layer RE is provided as necessary, and does not need to be provided. The coating layer RE may be a layer having a function other than the function of repelling an uncured resin. For example, a dielectric film or a dielectric multilayer film having a function of suppressing reflection on the top surface of the wavelength conversion member of the light incident on the top surface of the wavelength conversion member may be formed.

The configurations of the respective parts of Embodiments and Modifications in this description can be combined as necessary. For example, in any of Embodiments and Modifications, the radius of a plurality of projections and the number of projections to be arranged can be appropriately changed, and an additional structure of the second projection 34 and cylindrical lens-shaped structure, such as the projection 35, can also be incorporated.

For example, in any of Embodiments and Modifications, a structure of forming the light guide portion 70 and a structure of providing the transparent member 25 can also be incorporated.

For example, in any of Embodiments and Modifications, in a range in which the projection arranged at the outermost periphery of the optical functional unit 30 overlaps with the outer edge of the top surface of the light-emitting portion 20 in top view, or in a range of the same extent as the overlapping, the size relationship and the positional relationship between the outer shape of the optical functional unit, the outer shape of the wavelength conversion member 22, and the outer shape of the semiconductor light-emitting element can be adjusted.

For example, in any of Embodiments and Modifications, the arrangement of the light reflecting member 50 can be changed as necessary, and a structure covering the internal surface of the recess of the substrate 10, the outer surface of the spacer portion of the optical functional unit, and a part of the lower end region of the outer surface of the base portion of the optical functional unit, and the like can also be incorporated.

For example, in any of Embodiments and Modifications, as described in the light-emitting device 1I of Modification 6, a structure in which the side surface of the semiconductor light-emitting element 21 or the side surface of the wavelength conversion member 22 is covered with the light guide portion 70 made of a light-transmitting resin up to the upper end and the light reflecting member 50 is formed on the top surface of the light guide portion 70 can also be incorporated. In this case, similarly to Modification 7, the light reflecting member 50 is preferably formed to cover the outer surface of the spacer portion 33 and a part of the region from the lower end of the side surface of the base portion of the optical functional unit.

For example, in any of Embodiments and Modifications, any combination of a structure in which the low refractive-index portion 40 is provided in a space formed in the wavelength conversion member 22, a structure in which the through-hole 31H is formed at the base portion of the optical functional unit, a structure in which a low refractive index material other than air is used for the low refractive-index portion 40A to allow the adjustment of the refractive index difference with the optical functional unit, a structure in which the light shielding film 61 with an opening is provided on the top surface 22S of the wavelength conversion member 22, a structure in which the optical multilayer film 62 is provided on the top surface 22S of the wavelength conversion member 22, a structure in which the shape of the base portion of the optical functional unit is changed, a structure in which the expanded portion EX is provided at the outer surface of the spacer portion of the optical functional unit, and the like can be made.

Thus, the respective embodiments are not intended to limit the scope of the invention. The respective embodiments and the respective modifications can be performed in other various forms, and various kinds of omissions, replacements, and changes are allowed without departing from the gist of the invention. Those modifications are included in the scope and gist of the invention as well as in the scope of the invention described in the scope of the patent claim and its equals.

### DESCRIPTION OF REFERENCE SIGNS

1,2 light-emitting device
10 substrate
20 light-emitting portion
21 semiconductor light-emitting element
22 wavelength conversion member
25 transparent member
30,80 optical functional unit
31,81 base portion
32, 34, 82 projection
26, 33, 52, 83 spacer portion
36 protruding portion
40 low refractive-index portion
50 light reflecting portion
61 light shielding film
62 optical multilayer film
70 light guide portion

1. A light-emitting device comprising:
a substrate;
a light-emitting portion that is disposed on the substrate, includes a semiconductor light-emitting element with a light-emitting layer, and has a top surface from which an emitted light from the light-emitting layer is emitted;
an optical functional unit that is made of a transparent material and includes a base portion and a plurality of projections formed on the base portion, the base portion being continuously extending to cover the top surface of the light-emitting portion;
a spacer portion that separates the top surface of the light-emitting portion and a lower surface of the base portion opposed to each other by a predetermined distance to form a gap between the top surface of the light-emitting portion and the lower surface of the base portion;
a light reflecting portion that is made of a material with a light reflectivity and covers a side surface of the light-emitting portion, a side surface of the spacer portion, or at least a part of a side surface of the base portion; and
a low refractive-index portion provided inside the gap and made of a low refractive-index material having a small refractive index compared with the optical functional unit: wherein
the semiconductor light-emitting element has a top surface including a light-emitting region from which the emitted light from the light-emitting layer is emitted upward.
the light-emitting portion includes a wavelength conversion member that is disposed on the top surface of the semiconductor light-emitting element and converts a wavelength of a part of the emitted light emitted from the light-emitting region.
the wavelength conversion member has a side surface covered with the light reflecting portion,
the base portion of the optical functional unit has a rectangular outer shape in top view,
the plurality of projections are arranged in a matrix, and
the optical functional unit is formed in a manner in which the wavelength conversion member is disposed immediately below all the projections arranged at an outermost periphery among the plurality of projections.

2. The light-emitting device according to claim 1, wherein
the spacer portion is provided with a protruding portion protruding downward from the lower surface of the base portion, a protruding portion protruding upward from the top surface of the light-emitting portion, or a member disposed between the top surface of the light-emitting portion and the lower surface of the base portion.

3. The light-emitting device according to claim 2, wherein
the spacer portion is formed along an outer edge of the lower surface of the base portion.

4. (canceled)

5. The light-emitting device according to claim 1, wherein
the wavelength conversion member has a lower surface in a shape approximately matched with a shape of the light-emitting region in the top surface of the semiconductor light-emitting element.

6. The light-emitting device according to claim 1, wherein
the wavelength conversion member of the light-emitting portion has a narrowed portion with an inclined surface inclined inward at a part of the side surface.

7. The light-emitting device according to claim 1, wherein
the plurality of projections of the optical functional unit have hemisphere surfaces projecting upward or aspheric surfaces.

8. (canceled)

9. The light-emitting device according to claim 1, wherein
the optical functional unit has an outer edge end portion at a position approximately matched with an outer edge of a top surface of the wavelength conversion member or a position outside with respect to the outer edge of the top surface of the wavelength conversion member in top view.

10. A light-emitting device comprising:
a substrate:
a light-emitting portion that is disposed on the substrate, includes a semiconductor light-emitting element with a light-emitting layer, and has a top surface from which an emitted light from the light-emitting layer is emitted;
an optical functional unit that is made of a transparent material and includes a base portion and a plurality of projections formed on the base portion, the base portion being continuously extending to cover the top surface of the light-emitting portion:
a spacer portion that separates the top surface of the light-emitting portion and a lower surface of the base portion opposed to each other by a predetermined distance to form a gap between the top surface of the light-emitting portion and the lower surface of the base portion:
a light reflecting portion that is made of a material with a light reflectivity and covers a side surface of the light-emitting portion, a side surface of the spacer portion, or at least a part of a side surface of the base portion; and
a low refractive-index portion provided inside the gap and made of a low refractive-index material having a small refractive index compared with the optical functional unit; wherein
the base portion of the optical functional unit has a rectangular outer shape in top view, and
the low refractive-index portion has a thickness in a range of 0.1% or more and 20% or less with respect to a length of one side of a top surface of the base portion of the optical functional unit.

11. The light-emitting device according to claim 1, wherein
the base portion of the optical functional unit has a rectangular outer shape in top view, and
the low refractive-index portion has a thickness in a range of 0.1% or more and 10% or less with respect to a length of one side of a top surface of the base portion of the optical functional unit.

12. The light-emitting device according to claim 1, wherein
the low refractive-index portion is configured of air filling the gap.

13. A light-emitting device comprising:
a substrate;
a light-emitting portion that is disposed on the substrate, includes a semiconductor light-emitting element with a light-emitting layer, and has a top surface from which an emitted light from the light-emitting layer is emitted;
an optical functional unit that is made of a transparent material and includes a base portion and a plurality of projections formed on the base portion, the base portion being continuously extending to cover the top surface of the light-emitting portion;
a spacer portion that separates the top surface of the light-emitting portion and a lower surface of the base portion opposed to each other by a predetermined distance to form a gap between the top surface of the light-emitting portion and the lower surface of the base portion;
a light reflecting portion that is made of a material with a light reflectivity and covers a side surface of the light-emitting portion, a side surface of the spacer portion, or at least a part of a side surface of the base portion; and
a low refractive-index portion provided inside the gap and made of a low refractive-index material having a small refractive index compared with the optical functional unit: wherein
the low refractive-index portion is configured of a resin material containing porous silica or hollow silica filled in the gap.

14. A light-emitting device comprising:
a substrate;
a light-emitting portion that is disposed on the substrate, includes a semiconductor light-emitting element with a light-emitting layer, and has a top surface from which an emitted light from the light-emitting layer is emitted;
an optical functional unit that is made of a transparent material and includes a base portion and a plurality of projections formed on the base portion, the base portion being continuously extending to cover the top surface of the light-emitting portion;
a spacer portion that separates the top surface of the light-emitting portion and a lower surface of the base portion opposed to each other by a predetermined distance to form a gap between the top surface of the light-emitting portion and the lower surface of the base portion;
a light reflecting portion that is made of a material with a light reflectivity and covers a side surface of the light-emitting portion, a side surface of the spacer portion, or at least a part of a side surface of the base portion; and
a low refractive-index portion provided inside the gap and made of a low refractive-index material having a small refractive index compared with the optical functional unit: wherein
the projection arranged at an outer periphery of the optical functional unit among the plurality of projections has a flat side surface extending in a direction along a side surface of the base portion at a side surface along the outer periphery of the projection,
the plurality of projections includes a first part having a rectangular cross section intersecting with the flat side surface and perpendicular to the flat side surface, and a second part that is formed on a top surface of the first part and provided with a spherical cap-shaped curved surface, and
the spherical cap-shaped curved surface has a polar angle of 26° or more and 90° or less.

15. (canceled)
